(19) United States
(12) Patent Application Publication
(10) Pub. No.: US 2025/0088206 A1
(43) Pub. Date: Mar. 13, 2025

(54) RECEIVER AND COMMUNICATION DEVICE

(71) Applicant: Murata Manufacturing Co., Ltd., Nagaokakyo-shi (JP)

(72) Inventor: Hajime KANDO, Nagaokakyo-shi (JP)

(21) Appl. No.: 18/911,596

(22) Filed: Oct. 10, 2024

Related U.S. Application Data
(63) Continuation of application No. PCT/JP2023/013811, filed on Apr. 3, 2023.

(30) Foreign Application Priority Data
Apr. 28, 2022 (JP) 2022-074685

(51) Int. Cl. H04B 1/00; H03H 9/145; H03H 9/64

(52) U.S. Cl. CPC H04B 1/0014; H03H 9/145; H03H 9/6413

(57) ABSTRACT

A receiver includes a quadrature mixer to perform frequency conversion to convert a radio-frequency signal into an I signal and a Q signal that have a 90° phase difference from each other and a surface acoustic wave (SAW) device to perform phase conversion on the I signal and the Q signal that are output from the quadrature mixer. In the SAW device, when α° represents a phase rotation amount of the I signal, β° represents a phase rotation amount of the Q signal, and n is an integer, (α+90±n×360−35.1)≤β≤(α+90+n×360+35.1) or (α−90+n×360−35.1)≤β≤(α−90+n×360+35.1).

### CROSS REFERENCE TO RELATED APPLICATIONS

This application claims the benefit of priority to Japanese Patent Application No. 2022-074685 filed on Apr. 28, 2022 and is a Continuation Application of PCT Application No. PCT/JP2023/013811 filed on Apr. 3, 2023. The entire contents of each application are hereby incorporated herein by reference.

### BACKGROUND OF THE INVENTION

### 1. Field of the Invention

The present invention relates to receivers and communication devices.

### 2. Description of the Related Art

“A 2.5 to 4.5 GHZ Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286 discloses a mixer-first acoustic filtering front-end circuit (receiver) incorporating a mixer (N-Path Switched-LC Mixer) positioned in the subsequent stage after an antenna, as well as an acoustic wave filter (Acoustic filter) positioned in the subsequent stage after the mixer. Specifically, FIG. 5 of “A 2.5 to 4.5 GHz Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286 illustrates a receiver incorporating a quadrature mixer implemented by differential input-differential output Gilbert cell mixers, positioned in the subsequent stage after signal input terminals (RF Input), a 90° phase shifter and a balun positioned in the subsequent stage after the Q path of the quadrature mixer, and a surface acoustic wave (SAW) band pass filter positioned in the subsequent stage after the balun.

The differential signals input from the signal input terminals are divided into the I path and the Q path and input to the quadrature mixer. The quadrature mixer, using mixers positioned in the I path and the Q path, modulates signals to intermediate frequency signals (IF signals) that have a 90° phase difference between the I path and the Q path. The signals are subjected to phase rotation using the balun positioned in the subsequent stage after the quadrature mixer and the 90° phase shifter positioned in the Q path. As a result, the desired signal in the Q path is in antiphase with the signal in the I path, whereas the image signals are in phase. By combining these desired signals and image signals using the balun, the image signals that are in phase are canceled out, while the antiphase desired signals are extracted, converted to a non-differential signal, and output. As such, passing radio-frequency signals in different frequency ranges through a single surface acoustic wave band pass filter positioned in the subsequent stage after the quadrature mixer enables radio-frequency signal reception processing with low loss.

However, the receiver in “A 2.5 to 4.5 GHz Switched-LC-Mixer-First Acoustic-Filtering RF Front-End Achieving <6 dB NF, +30 dBm IIP3 at 1×Bandwidth Offset”, H. Seo and J. Zhou, IEEE RFIC, 2020, pp. 283-286 requires multiple baluns and LC circuits between the output end of the mixer and the input end of the surface acoustic wave band pass filter for phase conversion and balanced/unbalanced conversion, which increases the circuit size.

### SUMMARY OF THE INVENTION

Example embodiments of the present invention provide low-loss miniaturized mixer-first receivers and low-loss miniaturized communication devices.

A receiver according to an example embodiment of the present invention includes a quadrature mixer to perform frequency conversion to convert a radio-frequency signal into an I signal and a Q signal that have a 90° phase difference from each other and an acoustic wave device to perform phase conversion on the I signal and the Q signal that are output from the quadrature mixer. In the acoustic wave device, when α° represents the phase rotation amount of the I signal, β° represents the phase rotation amount of the Q signal, and n is an integer, (α+90+n×360−35.1)≤β≤(α+90+n×360+35.1) or (α−90+n×360−35.1)≤β≤(α−90+n×360+35.1).

Example embodiments of the present invention provide low-loss miniaturized mixer-first receivers and low-loss miniaturized communication devices.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of a receiver and a communication device according to an example embodiment of the present invention.

FIG. 2A illustrates an example of an electrode configuration in a longitudinally coupled surface acoustic wave (SAW) filter.

FIG. 2B illustrates a schematic representation of the longitudinally coupled SAW filter.

FIG. 3 illustrates an example of a circuit configuration of a SAW device included in a receiver according to an example embodiment of the present invention.

FIG. 4A is a circuit configuration diagram of a receiver according to a first modification of an example embodiment of the present invention.

FIG. 4B is a timing chart illustrating a drive signal of a quadrature mixer according to the first modification.

FIG. 5 illustrates an example of a circuit configuration of an SAW device included in the receiver according to the first modification.

FIG. 6 illustrates an example of a circuit configuration of an SAW device included in a receiver according to a second modification of an example embodiment of the present invention.

### DETAILED DESCRIPTION OF THE EXAMPLE EMBODIMENTS

Hereinafter, example embodiments of the present invention and modifications thereof will be described in detail with reference to the drawings. The example embodiments and modifications thereof described below provide comprehensive or specific examples. Details, such as numerical values, shapes, materials, elements, and arrangements and connection configurations of the elements provided in the following example embodiments and modifications thereof are illustrative and are not intended to limit the scope of the present invention. Among the elements in the following example embodiments and modifications thereof, elements not recited in any of the independent claims are described as optional elements. The size or size ratio of the elements illustrated in the drawings is not necessarily depicted with precision.

In the following example embodiments, the term “signal path” refers to a transfer line defined by, for example, wire lines to transfer radio-frequency signals, circuit elements and electrodes directly coupled to the wire lines, and terminals directly coupled to the wire lines or electrodes.

In the following example embodiments, the term “couple” applies when one circuit element is directly coupled to another circuit element via a connection terminal and/or an interconnect conductor. The term also applies when one circuit element is electrically coupled to another circuit element via another circuit element. The expression “coupled between A and B” means that a circuit element is coupled to A and B in a path connecting A and B.

In the following, a situation where two signals are in phase means that the phases of the two signals are within a range that can be considered equivalent or substantially equivalent, such as a range with phase differences of several percent. The situation where two signals are in antiphase means that the phase difference between the two signals is 180° or substantially 180°, for example, when the phase difference is 180° plus or minus several percent.

### Example Embodiments

### 1. Circuit Configuration of Receiver 1 and Communication Device 5

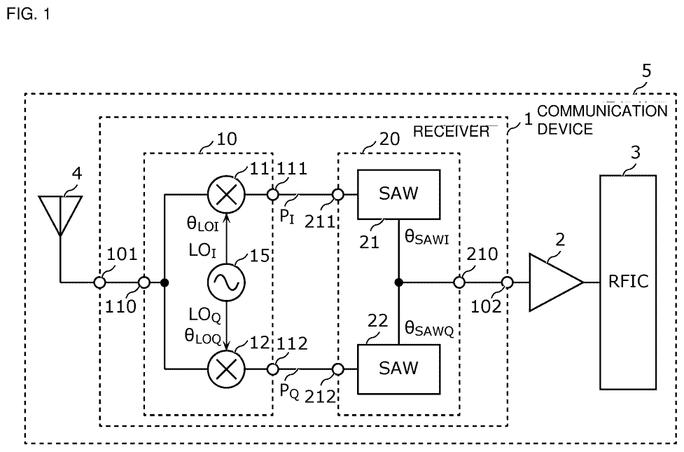

A circuit configuration of a receiver 1 and a communication device 5 according to an example embodiment of the present invention will be described with reference to FIG. 1.

### 1.1 Circuit Configuration of Communication Device 5

First, a circuit configuration of the communication device 5 will be described. As illustrated in FIG. 1, the communication device 5 according to the present example embodiment includes the receiver 1, a low-noise amplifier 2, a radio-frequency (RF) signal processing circuit (RFIC) 3, and an antenna 4.

The receiver 1 is configured to transfer radio-frequency signals between the antenna 4 and the RFIC 3. A detailed circuit configuration of the receiver 1 will be described later.

The low-noise amplifier 2 is operable to amplify radio-frequency signals output from a signal output terminal 102 of the receiver 1. The input end of the low-noise amplifier 2 is coupled to the signal output terminal 102, and the output end of the low-noise amplifier 2 is coupled to the RFIC 3.

The antenna 4 is coupled to an antenna connection terminal 101 of the receiver 1. The antenna 4 is operable to receive radio-frequency signals from outside and outputs radio-frequency signals to the receiver 1.

The RFIC 3 is an example of a signal processing circuit to process radio-frequency signals. Specifically, the RFIC 3 is operable to process receive signals inputted through receive paths of the receiver 1 and output the receive signals generated through the signal processing to, for example, a baseband signal processing circuit (BBIC, not illustrated). The RFIC 3 includes a controller configured or programmed to control circuit elements, such as switches included in the receiver 1, based on information about the bands (frequency ranges) of radio-frequency signals that the receiver 1 can transfer. The function of the controller of the RFIC 3 may be partially or entirely provided outside the RFIC 3. For example, the function of the controller of the RFIC 3 may be partially or entirely provided in the BBIC or the receiver 1.

In the communication device 5 according to the present example embodiment, the antenna 4 is a non-essential element.

The communication device 5 may also include a transmitter that outputs radio-frequency signals processed by the RFIC 3 to the antenna 4. In this case, the RFIC 3 is also operable to process, for example by up-conversion, transmit signals inputted from the BBIC and output the transmit signals generated by the signal processing to the transmitter.

### 1.2 Circuit Configuration of Receiver 1

Next, a circuit configuration of the receiver 1 will be described. As illustrated in FIG. 1, the receiver 1 includes a quadrature mixer 10, an SAW device 20, the antenna connection terminal 101, and the signal output terminal 102.

The quadrature mixer 10 includes mixers 11 and 12, a local oscillation circuit 15, an input terminal 110, an output I-terminal 111, and an output Q-terminal 112.

The mixer 11 is an example of a first mixer. The mixer 11 is operable to perform frequency conversion to convert radio-frequency signals input from the input terminal 110 into I signals and output the I signals from the output I-terminal 111. The mixer 12 is an example of a second mixer. The mixer 12 is operable to perform frequency conversion to convert radio-frequency signals input from the input terminal 110 into Q signals, which have a 90° phase difference from I signals, and output the Q signals from the output Q-terminal 112. In other words, the quadrature mixer 10 performs frequency conversion to convert radio-frequency signals into I signals and Q signals that have a 90° phase difference from each other.

The SAW device 20 is an example of an acoustic wave device. The SAW device 20 includes SAW phase shifter circuits 21 and 22, an input I-terminal 211 and an input Q-terminal 212, and an output terminal 210. The input I-terminal 211 is coupled to the output I-terminal 111, and the input Q-terminal 212 is coupled to the output Q-terminal 112. The SAW phase shifter circuit 21 is operable to perform phase conversion on the I signal transferred in a path P_{I} connecting the mixer 11 and the SAW phase shifter circuit 21. The SAW phase shifter circuit 22 is operable to perform phase conversion on the Q signal transferred in a path Po connecting the mixer 12 and the SAW phase shifter circuit 22. The SAW phase shifter circuit 21 may be, for example, a filter circuit that has a pass band including the frequency of the I signal, and the SAW phase shifter circuit 22 may be a filter circuit that has a pass band including the frequency of the Q signal. The SAW phase shifter circuits 21 and 22 are not necessarily provided separately. The SAW phase shifter circuits 21 and 22 may be provided collectively, for example, in a manner where an IDT electrode coupled to the input I-terminal 211, an IDT electrode coupled to the input Q-terminal 212, and an IDT electrode coupled to the output terminal 210 are provided in a single surface acoustic wave propagation path.

Here, the operating principles of the receiver 1 according to the present example embodiment are described.

The receiver 1 performs frequency conversion and phase conversion on radio-frequency signals at a frequency F_{RF}, which is input from the antenna connection terminal 101, and outputs the radio-frequency signals to the low-noise amplifier 2 and the RFIC 3 in a low-loss manner. To perform receive processing on radio-frequency signals of multiple bands, known receivers require multiple receive filters that support the frequencies of radio-frequency signals. In this regard, since the receiver 1 according to the present example embodiment converts multiple radio-frequency signals at the frequency F_{RF}, which can vary, into signals at a desired frequency, receive processing can be performed using a single filter that supports the desired frequency.

A radio-frequency signal including a desired signal D and an image signal IM is input to the input terminal 110 and divided between the mixers 11 and 12. At this time, a desired signal D_{I} and an image signal IM_{I} input to the mixer 11 are respectively modulated to frequencies (−F_{IF}) and (+F_{IF}), and the desired signal D_{I} and the image signal IM_{I} become in phase. A desired signal D_{Q} and an image signal IM_{Q} input to the mixer 12 are respectively modulated to frequencies (−F_{IF}) and (+F_{IF}), the desired signal D_{Q} is rotated by about 90° (or about −90°) with respect to the desired signal D_{I}, and the image signal IM_{Q} is rotated by about −90° (or about 90°) with respect to the image signal IM_{I}. The following continues the description using mathematical expressions.

Provided that LO_{I} represents a local signal output from the local oscillation circuit 15 to the mixer 11, and LO_{Q} represents a local signal output from the local oscillation circuit 15 to the mixer 12, the desired signals D_{I} and D_{Q}, the image signals IM_{I} and IM_{Q}, and the local signals LO_{I} and LO_{Q} are expressed as Expressions 1 and 2.

$$D = {D}_{I} + {D}_{Q} IM = {IM}_{I} + I {M}_{Q} {ω}_{R F} = {ω}_{L O} + {ω}_{IF} , {F}_{R F} = {F}_{L O} + {F}_{I F} {ω}_{IM} = {ω}_{L O} - {ω}_{IF} , {F}_{IM} = {F}_{L O} - {F}_{IF} \qquad Expression 1 :$$

$${D}_{I} = {D}_{Q} = {A}_{R F} \frac{{e}^{j ( {ω}_{L O} - {ω}_{IF} ) t} + {e}^{- j ( {ω}_{L O} - {ω}_{IF} ) t}}{2} I {M}_{I} = {IM}_{Q} = {A}_{IM} \frac{{e}^{j ( {ω}_{L O} - {ω}_{IF} ) t} + {e}^{- j ( {ω}_{L O} - {ω}_{IF} ) t}}{2} {LO}_{I} = \frac{{e}^{j {ω}_{LO} t} + {e}^{- j {ω}_{LO} t}}{2} L {O}_{Q} = \frac{{e}^{j {ω}_{LO} t} + {e}^{- j {ω}_{LO} t}}{2 j} \qquad Expression 2 :$$

When the desired signal D_{I} and the local signal LO_{I} are multiplied by the mixer 11, and the high-frequency component (2ω_{LO}+ω_{IF}) is ignored, a desired signal D_{I}LO_{I} output from the mixer 11 is expressed as Expression 3.

$${D}_{I} L {O}_{I} = \frac{{A}_{R F}}{2} cos {ω}_{IF} t \qquad Expression 3 :$$

When the image signal IM_{I} and the local signal LO_{I} are multiplied by the mixer 11, and the high-frequency component is ignored, an image signal IM_{I}LO_{I} output from the mixer 11 is expressed as Expression 4.

$${IM}_{I} L {0}_{I} = \frac{{A}_{IM}}{2} cos {ω}_{IF} t \qquad Expression 4 :$$

As expressed as Expressions 3 and 4, both of the desired signal D_{I}LO_{I} and the image signal IM_{I}LO_{I} in the path PI are converted to an IF band, phase-aligned, and output from the mixer 11.

When the desired signal D_{Q} and the local signal LO_{Q} are multiplied by the mixer 12, and the high-frequency component is ignored, a desired signal D_{Q}LO_{Q} output from the mixer 12 is expressed as Expression 5.

$${D}_{Q} L {O}_{Q} = \frac{{A}_{RF}}{2} sin {ω}_{I F} t \qquad Expression 5 :$$

When the image signal IM_{Q} and the local signal LO_{Q} are multiplied by the mixer 12, and the high-frequency component is ignored, an image signal IM_{Q}LO_{Q} output t from the mixer 12 is expressed as Expression 6.

$${IM}_{Q} L {0}_{Q} = \frac{{A}_{IM}}{2} sin {ω}_{IF} t \qquad Expression 6 :$$

As expressed as Expressions 5 and 6, both of the desired signal D_{Q}LO_{Q} and the image signal IM_{Q}LO_{Q} in the path P_{Q} are converted to an IF band, phase-opposed, and output from the mixer 12.

The desired signal D_{I}LO_{I} and the image signal IM_{I}LO_{I} transferred in the path P_{I} are input to the input I-terminal 211, phase-converted by the SAW phase shifter circuit 21, filtered as necessary, and output to the output terminal 210. The phases of the desired signal D_{I}LO_{I} and the image signal IM_{I}LO_{I} output from the SAW phase shifter circuit 21 are, for example, both 0° (no phase rotation) and in phase. Thus, provided that B_{SAW} represents the conversion gain of the SAW phase shifter circuit 21, the desired signal D_{I}LO_{I} output from the SAW phase shifter circuit 21 is expressed as Expression 7, and the image signal IM_{I}LO_{I} output from the SAW phase shifter circuit 21 is expressed as Expression 8.

$${D}_{I} {LO}_{I} = {B}_{S A W} \frac{{A}_{R F}}{2} cos {ω}_{IF} t \qquad Expression 7 :$$

$${IM}_{I} L {0}_{I} = {B}_{SAW} \frac{{A}_{IM}}{2} cos {ω}_{IF} t \qquad Expression 8 :$$

The desired signal D_{Q}LO_{Q} and the image signal IM_{Q}LO_{Q} transferred in the path P_{Q} are input to the input Q-terminal 212, phase-converted by the SAW phase shifter circuit 22, filtered as necessary, and output to the output terminal 210. The phases of the desired signal D_{Q}LO_{Q} and the image signal IM_{Q}LO_{Q} output from the SAW phase shifter circuit 22 are, for example, both rotated by about 90°. As a result, the phase of the desired signal D_{Q}LO_{Q} becomes about 0°, while the phase of the image signal IM_{Q}LO_{Q} becomes about 180°. As a result, the desired signal D_{Q}LO_{Q} is in phase with the desired signal D_{I}LO_{I}, and the image signal IM_{Q}LO_{Q} is in antiphase with the image signal IM_{I}LO_{I}. Thus, provided that B_{SAW} represents the conversion gain of the SAW phase shifter circuit 22, the desired signal D_{Q}LO_{Q} output from the SAW phase shifter circuit 22 is expressed as Expression 9, and the image signal IM_{Q}LO_{Q} output from the SAW phase shifter circuit 22 is expressed as Expression 10.

$${D}_{Q} {LO}_{Q} = {B}_{SAW} \frac{{A}_{RF}}{2} cos {ω}_{IF} t \qquad Expression 9$$

$${IM}_{Q} {LO}_{Q} = - {B}_{SAW} \frac{{A}_{IM}}{2} cos {ω}_{IF} t \qquad Expression 10$$

When the I signal and the Q signal are combined at the output terminal 210, the image signal IM_{I}LO_{I} and the image signal IM_{Q}LO_{Q}, which are in antiphase with each other, are rejected, and the desired signal D_{I}LO_{I} and the desired signal D_{Q}LO_{Q}, which are in phase with each other, are extracted from the output terminal 210. A desired signal D_{OUT} and an image signal IM_{OUT} combined at the output terminal 210 are respectively expressed as Expressions 11 and 12.

$${D}_{OUT} = {B}_{SAW} {A}_{RF} cos {ω}_{IF} t \qquad Expression 11$$

$${IM}_{OUT} = 0 \qquad Expression 12$$

Provided that α° represents the phase rotation amount of the SAW phase shifter circuit 21, and (α+90)° represents the phase rotation amount of the SAW phase shifter circuit 22, the desired signal D_{OUT} and the image signal IM_{OUT} combined at the output terminal 210 are respectively expressed as Expressions 13 and 14.

$${D}_{OUT} = {B}_{SAW} {A}_{RF} cos ( {ω}_{IF} t + α ) \qquad Expression 13$$

$${IM}_{OUT} = 0 \qquad Expression 14$$

Table 1 indicates the relationship between the output signal output to the output terminal 210, the phase of the local signal to be multiplied by the quadrature mixer 10, and the phase rotation amount of the SAW device 20, for the desired signal D and the image signal IM. In Table 1, the conversion gain B_{SAW} is about 1, and the phase of the local signal LO_{I} and the phase rotation amount of the SAW phase shifter circuit 21 are both about 0°.

From Table 1, it is understood that when the phase of the local signal LO_{Q} and the phase rotation amount of the SAW phase shifter circuit 22 are both about +90° or about −90°, the desired signal D_{I}LO_{I} and the desired signal D_{Q}LO_{Q} are in phase, and the image signal IM_{I}LO_{I} and the image signal IM_{Q}LO_{Q} are in antiphase.

Additionally, from Table 1, it is understood that when the phase of the local signal LO_{Q} is about +90° and the phase rotation amount of the SAW phase shifter circuit 22 is about −90°, and when the phase of the local signal LO_{Q} is about −90° and the phase rotation amount of the SAW phase shifter circuit 22 is about +90°, the desired signal D_{I}LO_{I} and the desired signal D_{Q}LO_{Q} are in antiphase, and the image signal IM_{I}LO_{I} and the image signal IM_{Q}LO_{Q} are in phase.

TABLE 1

| | Signal | | | | |
|---|---|---|---|---|---|
| | multiplied by | Exponential form of output of | Trigonometric form of | Output of SAW device 20 | |
| Signal | mixer 10 | mixer 10 | output of mixer 10 | Phase rotation +90° | Phase rotation −90° |
| I-path desired | D_{I}·LO_{I}(+0°) | $\frac{{A}_{RF}}{4} ( {e}^{j {ω}_{IF} t} + {e}^{- j {ω}_{IF} t} )$ | $+ \frac{{A}_{RF}}{2} cos {ω}_{IF} t$ | — | — |
| signal | | | | | |
| D_{I} | | | | | |
| I-path image | IM_{I}·LO_{I}(+0°) | $\frac{{A}_{IM}}{4} ( {e}^{j {ω}_{IF} t} + {e}^{- j {ω}_{IF} t} )$ | $+ \frac{{A}_{IM}}{2} cos {ω}_{IF} t$ | — | — |
| signal | | | | | |
| IM_{I} | | | | | |
| Q-path desired | D_{Q}·LO_{Q}(+90°) | $\frac{{A}_{RF}}{4 j} ( {e}^{j {ω}_{IF} t} - {e}^{- j {ω}_{IF} t} )$ | $+ \frac{{A}_{RF}}{2} sin {ω}_{IF} t$ | $+ \frac{{A}_{RF}}{2} cos {ω}_{IF} t$ | $- \frac{{A}_{RF}}{2} cos {ω}_{IF} t$ |
| signal | | | | | |
| D_{Q} | | | | | |
| Q-path image | IM_{Q}·LO_{Q}(+90°) | $- \frac{{A}_{IM}}{4 j} ( {e}^{j {ω}_{IF} t} - {e}^{- j {ω}_{IF} t} )$ | $- \frac{{A}_{IM}}{2} sin {ω}_{IF} t$ | $- \frac{{A}_{IM}}{2} cos {ω}_{IF} t$ | $+ \frac{{A}_{IM}}{2} cos {ω}_{IF} t$ |
| signal | | | | | |
| IM_{Q} | | | | | |
| Q-path desired | D_{Q}·LO_{Q}(−90°) | $- \frac{{A}_{RF}}{4 j} ( {e}^{j {ω}_{IF} t} - {e}^{- j {ω}_{IF} t} )$ | $- \frac{{A}_{RF}}{2} sin {ω}_{IF} t$ | $- \frac{{A}_{RF}}{2} cos {ω}_{IF} t$ | $+ \frac{{A}_{RF}}{2} cos {ω}_{IF} t$ |
| signal | | | | | |
| D_{Q} | | | | | |
| Q-path image | IM_{Q}·LO_{Q}(−90°) | $\frac{{A}_{IM}}{4 j} ( {e}^{j {ω}_{IF} t} + {e}^{- j {ω}_{IF} t} )$ | $+ \frac{{A}_{IM}}{2} sin {ω}_{IF} t$ | $+ \frac{{A}_{IM}}{2} cos {ω}_{IF} t$ | $- \frac{{A}_{IM}}{2} cos {ω}_{IF} t$ |
| signal | | | | | |
| IM_{Q} | | | | | |

Table 2 indicates the conditions in which the desired signals D_{I}LO_{I} and D_{Q}LO_{Q} are in phase and the image signals IM_{I}LO_{I} and IM_{Q}LO_{Q} are in antiphase at the output terminal 210.

According to Table 2, (1) when the frequency of the desired signal D is F_{LO}+F_{IF}, the frequency of the image signal IM is F_{LO}−F_{IF}, and the phase of the local signal LO_{Q} and the phase rotation amount of the SAW phase shifter circuit 22 are both about +90° or −90°, the desired signal D_{I}LO_{I} and the desired signal D_{Q}LO_{Q} are in phase, and the image signal IM_{I}LO_{I} and the image signal IM_{Q}LO_{Q} are in antiphase. When the frequency of the desired signal D is F_{LO}−F_{IF}, the frequency of the image signal IM is F_{LO}+F_{IF}, and (2) when the phase of the local signal LO_{Q} is about +90° and the phase rotation amount of the SAW phase shifter circuit 22 is about −90°, and (3) when the phase of the local signal LO_{Q} is about −90° and the phase rotation amount of the SAW phase shifter circuit 22 is about +90°, the desired signal D_{I}LO_{I} and the desired signal D_{Q}LO_{Q} are in phase, and the image signal IM_{I}LO_{I} and the image signal IM_{Q}LO_{Q} are in antiphase.

Overall, it is understood that varying the frequency F_{LO} of the local signal changes the frequency of the desired signal D, which is to be extracted.

TABLE 2

| LO signal | Surface acoustic wave | | |
|---|---|---|---|
| phase | device phase rotation | Frequency of | Frequency of |
| difference | amount difference | desired RF | image signal |
| θ_{LOQ} − θ_{LOI} | θ_{SAWQ} − θ_{SAWI} | signal D F_{RF} | IM F_{IM} |
| +90° | +90° | F_{LO} + F_{IF} | F_{LO} − F_{IF} |
| +90° | −90° | F_{LO} − F_{IF} | F_{LO} + F_{IF} |
| −90° | +90° | F_{LO} − F_{IF} | F_{LO} + F_{IF} |
| −90° | −90° | F_{LO} + F_{IF} | F_{LO} − F_{IF} |

As indicated in Table 1, when the phase difference between the local signals LO_{Q} and LO_{I} is a predetermined phase difference, ∞ is obtained as the image rejection ratio.

Here, the ratio of the power (P_{D}) of the desired signal D to the power (P_{IM}) of the image signal IM is expressed as Expression 15. δ represents the amplitude error of the local signals LO_{I} and LO_{Q}, and φ represents the phase error of the local signals LO_{I} and LO_{Q}.

$$\frac{{P}_{D}}{{P}_{IM}} = \frac{{A}_{RF}^{2}}{{A}_{IM}^{2}} \cdot \frac{4}{{δ}^{2} + {φ}^{2}} \qquad Expression 15$$

The image rejection ratio IRR is obtained by dividing P_{D}/P_{IM} by A_{RF}²/A_{IM}², which is expressed as Expression 16.

$$IRR = \frac{4}{{δ}^{2} + {φ}^{2}} \qquad Expression 16$$

When the image rejection ratio IRR is represented in units of dB, the image rejection ratio IRR is expressed as Expression 17.

$$IRR ( dB ) = 6 - 10 {log}_{10} ( {δ}^{2} + {φ}^{2} ) \qquad Expression 17$$

In Expression 17, when δ=0 and φ=about 1.15°, the IRR is about 40 dB. When δ=0 and φ=about 11.42°, the IRR is about 20 dB. When δ=0 and φ=about 35.1°, the IRR is about 10 dB.

The receiver 1 according to the present example embodiment requires an image rejection ratio IRR of about 10 dB, for example. By securing an image rejection ratio IRR of at least about 10 dB and optimizing the phase rotation amount of the quadrature mixer 10 and the SAW device 20, the receive sensitivity necessary for the receiver 1 as a mobile communication device can be achieved.

When the SAW phase shifter circuits 21 and 22 differ in conversion gain, the division ratio of the I signal and the Q signal may be adjusted by modifying the amplitude gain in the circuit incorporating resistors, inductors, and capacitors, or by adjusting the impedance of the mixers 11 and 12. The amplitudes of the image signals IM_{I} and IM_{Q} output to the output terminal 210 may be equalized sufficiently to satisfy the required image rejection ratio.

Specifically, in the receiver 1 according to the present example embodiment, when the phase rotation amount of the I signal in the path P_{I} is α′, the phase rotation amount of the Q signal in the path Po is β°, and n is an integer, the relationship expressed in Expression 18 or 19 is satisfied.

$$( α + 90 + n \times 360 - 35.1 ) \leq β \leq ( α + 90 + n \times 360 + 35.1 ) \qquad Expression 18$$

$$( α - 90 + n \times 360 - 35.1 ) \leq β \leq ( α - 90 + n \times 360 + 35.1 ) \qquad Expression 19$$

As such, the image signal IM generated by the quadrature mixer 10 can be reduced or prevented by the SAW device 20 with an image rejection ratio of about 10 dB or more. The SAW device 20 for phase conversion is positioned between the output end of the quadrature mixer 10 and the signal output terminal 102. With this configuration, the low-loss miniaturized mixer-first receiver 1 is provided.

More specifically, (1) when the mixer 11 is driven at 0°, the mixer 12 is driven at about +90°, the phase rotation amount of the SAW phase shifter circuit 21 is α°, and the phase rotation amount of the SAW phase shifter circuit 22 is about (α+90), the radio frequency-signal frequency F_{RF} (=F_{LO}+F_{IF}) can be changed by varying the local-signal frequency F_{LO}.

(2) When the mixer 11 is driven at about 0°, the mixer 12 is driven at about +90°, the phase rotation amount of the SAW phase shifter circuit 21 is α°, and the phase rotation amount of the SAW phase shifter circuit 22 is about (α−90)°, the radio frequency-signal frequency F_{RF} (=F_{LO}−F_{IF}) can be changed by varying the local-signal frequency F_{LO}.

(3) When the mixer 11 is driven at about 0°, the mixer 12 is driven at about −90°, the phase rotation amount of the SAW phase shifter circuit 21 is α°, and the phase rotation amount of the SAW phase shifter circuit 22 is about (α+90) °, the radio frequency-signal frequency F_{RF} (=F_{LO}−F_{IF}) can be changed by varying the local-signal frequency Fro.

(4) When the mixer 11 is driven at about 0°, the mixer 12 is driven at about −90°, the phase rotation amount of the SAW phase shifter circuit 21 is α°, and the phase rotation amount of the SAW phase shifter circuit 22 is about (α−90)°, the radio frequency-signal frequency F_{RF} (=F_{LO}+F_{IF}) can be changed by varying the local-signal frequency F_{LO}.

The SAW device 20 according to the present example embodiment may have, for example, the characteristics of a band pass filter with a pass band that includes a frequency range (frequency F_{IF}) of the desired signal D and an attenuation band outside the frequency range of the desired signal D. With the characteristics of such a band pass filter, in the SAW device 20, the insertion loss is reduced, the size is reduced, the non-linear distortion is reduced compared to polyphase filters or complex filters using resistors and semiconductors. Additionally, a steep attenuation characteristic can be achieved near the pass band, and unwanted signals outside the range of the desired signal D can be reduced or prevented.

Next, an example circuit configuration of the SAW device 20 will be presented.

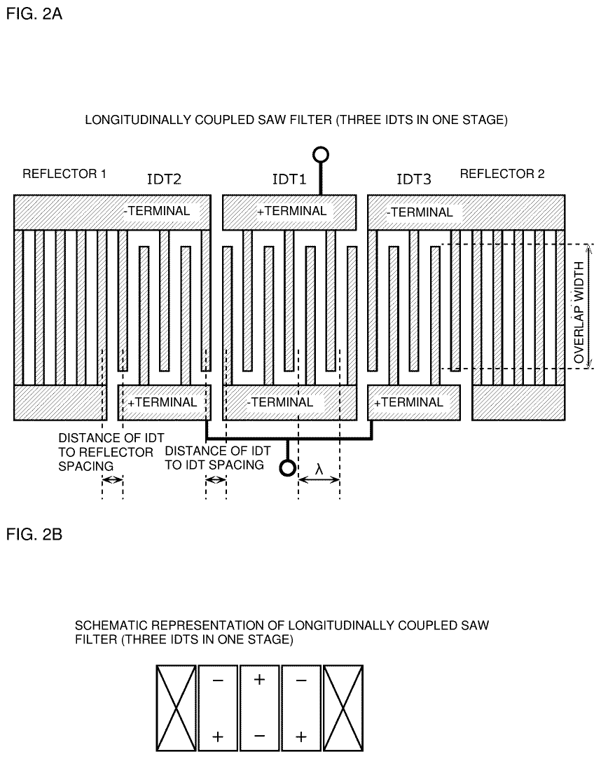

FIG. 2A illustrates an example of an electrode configuration in a longitudinally coupled SAW filter. FIG. 2B illustrates a schematic representation of the longitudinally coupled SAW filter. As illustrated in FIG. 2A, a longitudinally coupled SAW filter includes multiple interdigital transducer (IDT) electrodes and reflectors positioned on both sides of the IDT electrodes. Longitudinally coupled SAW filters have a filtering function achieved by exciting a resonant mode in which two or more surface acoustic waves resonate. This resonant mode is accomplished by controlling the number of pairs of electrode fingers of the IDT electrodes, the distance between the IDT electrodes (the distance of the IDT to IDT spacing), and the distance between the IDT electrodes and the reflectors (the distance of the IDT to the reflector spacing). Longitudinally coupled SAW filters are able to rotate the radio-frequency signal phase by controlling the distance between the IDT electrodes and the reflectors, the IDT electrode configuration, and the connection configuration between the IDT electrodes. By using a longitudinally coupled SAW filter as the SAW device 20, the SAW device 20 achieves both the phase rotation function and the filter function with a low-loss and steep attenuation characteristic.

In the following, to describe the configuration of the SAW device 20 provided by using the longitudinally coupled SAW filter, the electrode configuration in FIG. 2A will be illustrated using the schematic representation illustrated in FIG. 2B.

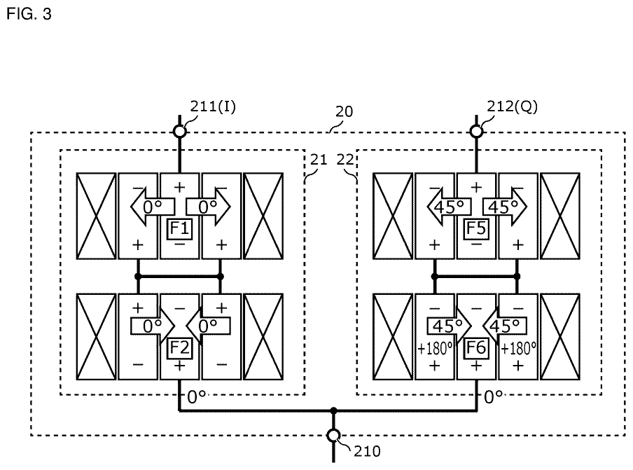

FIG. 3 illustrates an example of a circuit configuration of the SAW device 20 included in the receiver 1 according to the present example embodiment. The SAW phase shifter circuit 21 includes a longitudinally coupled SAW filter F1 including three IDT electrodes and two reflectors disposed on a substrate having piezoelectricity, and a longitudinally coupled SAW filter F2 including three IDT electrodes and two reflectors disposed on the substrate. The SAW phase shifter circuit 22 includes a longitudinally coupled SAW filter F5 including three IDT electrodes and two reflectors disposed on a substrate having piezoelectricity, and a longitudinally coupled SAW filter F6 including three IDT electrodes and two reflectors disposed on the substrate.

The + terminal of the central IDT electrode of the SAW filter F1 is coupled to the input I-terminal 211. The + terminals of the left and right IDT electrodes of the SAW filter F1 are coupled to the + terminals of the left and right IDT electrodes of the SAW filter F2. The + terminal of the central IDT electrode of the SAW filter F2 is coupled to the output terminal 210. The − terminals of the SAW filters F1 and F2 are grounded.

The + terminal of the central IDT electrode of the SAW filter F5 is coupled to the input Q-terminal 212. The + terminal of the left and right IDT electrodes of the SAW filter F5 is coupled to the − terminal of the left and right IDT electrodes of the SAW filter F6. The + terminal of the central IDT electrode of the SAW filter F6 is coupled to the output terminal 210. The − terminal of the SAW filter F5, the − terminal of the central IDT electrode of the SAW filter F6, and the + terminal of the left and right IDT electrodes of the SAW filter F6 are grounded.

With the configuration described above, in the SAW phase shifter circuit 21, no phase rotation is introduced between the IDT electrodes included in the SAW filters F1 and F2. By contrast, in the SAW phase shifter circuit 22, a 45° phase rotation is introduced between the central IDT electrode and the left and right IDT electrodes of the SAW filter F5, and a 45° phase rotation is introduced between the left and right IDT electrodes and the central IDT electrode of the SAW filter F6. This is because the SAW filters F5 and F6 differ from the SAW filters F1 and F2 in terms of the distance between the central IDT electrode and the left and right IDT electrodes and the distance between the left and right IDT electrodes and the reflectors. Additionally, a 180° phase rotation is introduced between the SAW filters F5 and F6. This is because the + terminals of the left and right IDT electrodes of the SAW filter F5 are coupled to the − terminals of the left and right IDT electrodes of the SAW filter F6.

Overall, the phase rotation amount of the I signal transferred from the input I-terminal 211 to the output terminal 210 is about 0°, and the phase rotation amount of the Q signal transferred from the input Q-terminal 212 to the output terminal 210 is about −90°.

Because multiple SAW filters are cascade-connected, the configuration described above achieves a steeper attenuation characteristic and greater attenuation compared to a single SAW filter. Furthermore, by reducing the phase rotation amount per stage of the SAW filter to less than about 90°, a total phase rotation of about 90° can be introduced by the SAW phase shifter circuit 21 or 22. This configuration easily matches the amplitude characteristics of the I signal and the Q signal.

Moreover, by reversing the polarities of the IDT electrodes of the SAW filter either positively or negatively, or by changing the IDT electrode distance by about ½ wavelength, the phase of the SAW phase shifter circuit 22 can be inverted by about 180°. This configuration enables, as desired, control over the relationship between the I signal and the Q signal output to the output terminal 210 and the relationship between the desired signal D and the image signal IM, with respect to the phase of the local signal multiplied by the quadrature mixer 10 and the phase rotation amount of the SAW device 20.

The phase rotation amounts of the SAW phase shifter circuits 21 and 22 may be controlled using a method (narrow-period electrode fingers) in which, for example, the spacing of the electrode finger close to an adjacent IDT electrode or the spacing of the electrode finger close to a reflector is narrowed in a particular IDT electrode compared to the electrode-finger spacing within the particular IDT electrode.

Since known transversal surface acoustic wave filters and surface acoustic wave filters provided using unidirectional IDT electrodes have linear phase slopes with respect to frequency, a 90° phase difference can be achieved by providing a first phase shifter circuit and a second phase shifter circuit using transversal surface acoustic wave filters or surface acoustic wave filters formed using unidirectional IDT electrodes. As a result, when the distance between the IDT electrodes is changed by about 0.25×wavelength, the first phase shifter circuit and the second phase shifter circuit are the same or substantially the same with respect to bandpass characteristics other than phase, maintaining linear phase slopes. As such, circuits with a 90° phase difference can be easily provided.

However, transversal surface acoustic wave filters and surface acoustic wave filters provided using unidirectional IDT electrodes have the disadvantage of high insertion loss, and thus cannot be used in circuits for handling radio frequencies. In contrast, longitudinally coupled surface acoustic wave filters have lower losses compared transversal surface acoustic wave filters and surface acoustic wave filters provided using unidirectional IDT electrodes that do not use the surface acoustic wave resonant mode. Therefore, by using longitudinally coupled SAW filters as the SAW phase shifter circuits 21 and 22, the SAW phase shifter circuits 21 and 22 achieve a wider pass band while maintaining band pass characteristics with lower loss and a steeper attenuation characteristic compared to surface acoustic wave phase shifters based on a transversal type using a wide pass band and a unidirectional IDT electrode.

### 1.3 Circuit Configuration of Receiver 1A According to First Modification of an Examiner Embodiment of the Present Invention

Next, a circuit configuration of a receiver 1A will be described.

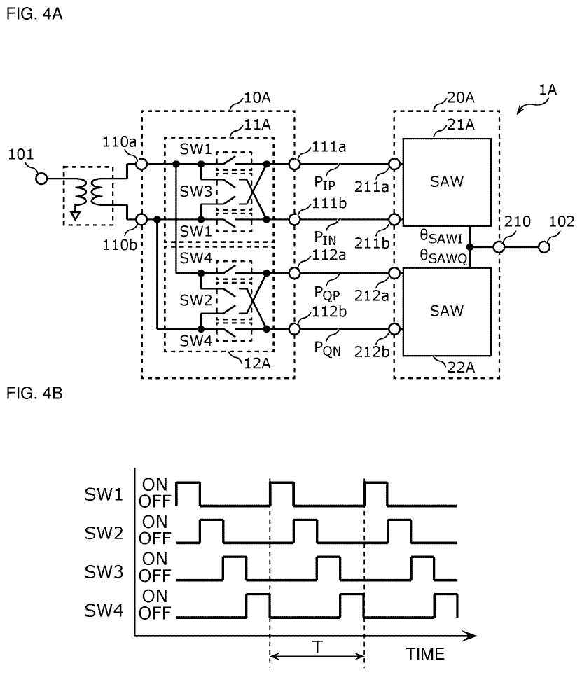

FIG. 4A is a circuit configuration diagram of a receiver 1A according to a first modification of an example embodiment of the present invention. FIG. 4B is a timing chart illustrating a drive signal of a quadrature mixer 10A according to the first modification. As illustrated in FIG. 4A, the receiver 1A includes the quadrature mixer 10A, an SAW device 20A, an antenna connection terminal 101, and a signal output terminal 102.

The receiver 1A may include a balun coupled between the antenna connection terminal 101 and the quadrature mixer 10A.

The quadrature mixer 10A includes mixer circuits 11A and 12A, an input terminal 110a (first differential input terminal) and an input terminal 110b (second differential input terminal), an output I-terminal 111a (first differential output I-terminal) and an output I-terminal 111b (second differential output I-terminal), and an output Q-terminal 112a (first differential output Q-terminal) and an output Q-terminal 112b (second differential output Q-terminal). A Gilbert cell mixer, for example, which is a double balanced mixer, is used as the quadrature mixer 10A.

The mixer circuit 11A is an example of a first mixer. The mixer circuit 11A is coupled between the input terminals 110a and 110b and the output I-terminals 111a and 111b. The mixer circuit 11A is operable to perform frequency conversion to convert antiphase radio-frequency differential signals input from the input terminals 110a and 110b into an I_{P} signal and an I_{N} signal, which are in antiphase, and output the I_{P} signal and the I_{N} signal respectively from the output I-terminals 111a and 111b. The mixer circuit 12A is an example of a second mixer. The mixer circuit 12A is coupled between the input terminals 110a and 110b and the output Q-terminals 112a and 112b. The mixer circuit 12A is operable to perform frequency conversion to convert antiphase radio-frequency differential signals input from the input terminals 110a and 110b into a Q_{P} signal and a Q_{N} signal, which are in antiphase and have a 90° phase difference from the I_{P} signal and the I_{N} signal, and output the Q_{P} signal and the Q_{N} signal respectively from the output Q-terminals 112a and 112b.

The mixer circuit 11A includes switches SW1 and SW3. The mixer circuit 12A includes switches SW2 and SW4. Of the switch SW1, a first end is coupled to the input terminal 110a, a second end is coupled to the input terminal 110b, a third end is coupled to the output I-terminal 111a, and a fourth end is coupled to the output I-terminal 111b. The switch SW1 is operable to synchronously control connection and disconnection between the first end and the third end and between the second end and the fourth end. Of the switch SW3, a first end is coupled to the input terminal 110a, a second end is coupled to the input terminal 110b, a third end is coupled to the output I-terminal 111b, and a fourth end is coupled to the output I-terminal 111a. The switch SW3 is operable to synchronously control connection and disconnection between the first end and the third end and between the second end and the fourth end. Of the switch SW2, a first end is coupled to the input terminal 110a, a second end is coupled to the input terminal 110b, a third end is coupled to the output Q-terminal 112b, and a fourth end is coupled to the output Q-terminal 112a. The switch SW2 is operable to synchronously control connection and disconnection between the first end and the third end and between the second end and the fourth end. Of the switch SW4, a first end is coupled to the input terminal 110a, a second end is coupled to the input terminal 110b, a third end is coupled to the output Q-terminal 112a, and a fourth end is coupled to the output Q-terminal 112b. The switch SW4 is operable to synchronously control connection and disconnection between the first end and the third end and between the second end and the fourth end.

As illustrated in FIG. 4B, the switch SW1 can be driven by a local signal with a 0° phase, the switch SW2 can be driven by a local signal with a −90° phase, the switch SW3 can be driven by a local signal with a 180° phase, and the switch SW4 can be driven by a local signal with a 90° (−270°) phase. Provided that T is the cycle of each local signal, the on-period of each switch is about T/4, for example.

The SAW device 20A is an example of an acoustic wave device according to an example embodiment. The SAW device 20A includes SAW phase shifter circuits 21A and 22A, an input I-terminal 211a (third differential input I-terminal) and an input I-terminal 211b (fourth differential input I-terminal), an input Q-terminal 212a (third differential input Q-terminal) and an input Q-terminal 212b (fourth differential input Q-terminal), and an output terminal 210 (fifth non-differential output terminal). The input I-terminal 211a is coupled to the output I-terminal 111a, the input I-terminal 211b is coupled to the output I-terminal 111b, the input Q-terminal 212a is coupled to the output Q-terminal 112a, and the input Q-terminal 212b is coupled to the output Q-terminal 112b. The SAW phase shifter circuit 21A is operable to perform phase conversion on an I_{P} signal transferred in a path PIP connecting the mixer circuit 11A and the SAW phase shifter circuit 21A and on an I_{N} signal transferred in a path PIN connecting the mixer circuit 11A and the SAW phase shifter circuit 21A. The SAW phase shifter circuit 22A is operable to perform phase conversion on a Q_{P} signal transferred in a path Pop connecting the mixer circuit 12A and the SAW phase shifter circuit 22A and on a Q_{N} signal transferred in a path P_{QN} connecting the mixer circuit 12A and the SAW phase shifter circuit 22A. The SAW phase shifter circuit 21 may be, for example, a filter circuit that has a pass band including the frequency of the I_{P} signal and the frequency of the I_{N} signal, and the SAW phase shifter circuit 22 may be a filter circuit that has a pass band including the frequency of the Q_{P} signal and the frequency of the Q_{N} signal.

Here, the operating principles of the receiver according to the present modification are described.

The receiver 1A performs frequency conversion and phase conversion on antiphase radio-frequency differential signals at a frequency F_{RF} and outputs the radio-frequency signals to the low-noise amplifier 2 and the RFIC 3 in a low-loss manner.

A radio-frequency signal including a desired signal D_{P} and an image signal IM_{P} is input to the input terminal 110a, and a radio-frequency signal including a desired signal D_{N} and an image signal IM_{N} is input to the input terminal 110b, and the radio-frequency signals are divided between the mixer circuits 11A and 12A. At this time, the desired signals Dip and D_{IN} and the image signals IM_{IP} and IM_{IN} input to the mixer circuit 11A are modulated to frequencies (−F_{IF}) and (+F_{IF}). The desired signal Dip and the image signals IM_{IP} are in phase, and the desired signal D_{IN} and the image signal IMIN are in phase. A desired signal D_{QP} and an image signal IM_{QP} input to the mixer circuit 12A are modulated to the frequencies (−F_{IF}) and (+F_{IF}). The desired signal D_{QP} is rotated by about 90° (or about −90°) with respect to the desired signal D_{IP}. The desired signal D_{QN} is rotated by about 90° (or about −90°) with respect to the desired signal D_{IN}. The image signal IM_{QP} is rotated by about −90° (or about 90°) with respect to the image signal IM_{IP}. The image signal IM_{QN} is rotated by about −90° (or about 90°) with respect to the image signal IM_{IN}.

Tables 3 and 4 indicate the relationships between the output signal output to the output terminal 210, the phase of the local signal to be multiplied by the quadrature mixer 10A, and the phase rotation amount (two-stage filter phase rotation amount) of the SAW device 20A, for the desired signal D and the image signal IM.

TABLE 3
F_{RF} = F_{LO} + F_{IF}, θ_{LOI} = 0°. Q_{LOQ} = +90°, mixer differential output, SAW device differential input/non-differential output

| | | | | | Output |
|---|---|---|---|---|---|
| | | | | | phase |
| | | | | | of |
| | | Local signal | | Output of | mixer |
| Signal | Input of mixer 10A | (phase) | Terminal | mixer 10A | 10A |
| Desired signal D | $+ \frac{{A}_{RF}}{4} ( {e}^{j ( {ω}_{LO} + {ω}_{IF} ) t} + {e}^{- j ( {ω}_{LO} + {ω}_{IF} ) t} )$ | $\frac{e \text{?} + e \text{?}}{2}$ | I+ | $+ \frac{A \text{?}}{8} ( e \text{?} + e \text{?} )$ | 0 |
| | $- \frac{{A}_{RF}}{4} ( {e}^{j ( {ω}_{LO} + {ω}_{IF} ) t} + {e}^{- j ( {ω}_{LO} + {ω}_{IF} ) t} )$ | (0) | I− | $- \frac{A \text{?}}{8} ( e \text{?} + e \text{?} )$ | 0 |
| | $+ \frac{{A}_{RF}}{4} ( {e}^{j ( {ω}_{LO} + {ω}_{IF} ) t} + {e}^{- j ( {ω}_{LO} + {ω}_{IF} ) t} )$ | $\frac{e \text{?} + e \text{?}}{2 j}$ | Q+ | $+ \frac{A \text{?}}{8} ( e \text{?} - e \text{?} )$ | $- \frac{π}{2}$ |
| | $- \frac{{A}_{RF}}{4} ( {e}^{j ( {ω}_{LO} + {ω}_{IF} ) t} + {e}^{- j ( {ω}_{LO} + {ω}_{IF} ) t} )$ | (π/2) | Q− | $- \frac{A \text{?}}{8} ( e \text{?} - e \text{?} )$ | $+ \frac{π}{2}$ |
| Image signal IM | $+ \frac{A \text{?}}{4} ( e \text{?} + e \text{?} )$ | $\frac{e \text{?} + e \text{?}}{2}$ | I+ | $+ \frac{A \text{?}}{8} ( e \text{?} + e \text{?} )$ | 0 |
| | $- \frac{A \text{?}}{4} ( e \text{?} + e \text{?} )$ | (0) | I− | $- \frac{A \text{?}}{8} ( e \text{?} + e \text{?} )$ | 0 |
| | $+ \frac{A \text{?}}{4} ( e \text{?} + e \text{?} )$ | $\frac{- e \text{?} + e \text{?}}{2 j}$ | Q+ | $- \frac{A \text{?}}{8} ( e \text{?} - e \text{?} )$ | $+ \frac{π}{2}$ |
| | $- \frac{A \text{?}}{4} ( e \text{?} + e \text{?} )$ | (π/2) | Q− | $+ \frac{A \text{?}}{8} ( e \text{?} - e \text{?} )$ | $- \frac{π}{2}$ |

| | Phase | | |
|---|---|---|---|
| | rotation | | |
| | amount | | |
| | of two- | | |
| | stage | | |
| Signal | filter | Output of two-stage filter | Output of SAW device 20A |
| Desired signal D | 0 | $+ {B}_{SAW} + \frac{A \text{?}}{8} ( e \text{?} + e \text{?} )$ | $+ {B}_{SAW} + \frac{A \text{?}}{8} ( e \text{?} + e \text{?} )$ |
| | Π | $+ {B}_{SAW} + \frac{A \text{?}}{8} ( e \text{?} + e \text{?} )$ | |
| | $+ \frac{π}{2}$ | $+ {B}_{SAW} + \frac{A \text{?}}{8} ( e \text{?} + e \text{?} )$ | |
| | $- \frac{π}{2}$ | $+ {B}_{SAW} + \frac{A \text{?}}{8} ( e \text{?} + e \text{?} )$ | |
| Image signal IM | 0 | $+ {B}_{SAW} + \frac{A \text{?}}{8} ( e \text{?} + e \text{?} )$ | 0 |
| | Π | $+ {B}_{SAW} + \frac{A \text{?}}{8} ( e \text{?} + e \text{?} )$ | |
| | $+ \frac{π}{2}$ | $- {B}_{SAW} + \frac{A \text{?}}{8} ( e \text{?} + e \text{?} )$ | |
| | $- \frac{π}{2}$ | $- {B}_{SAW} + \frac{A \text{?}}{8} ( e \text{?} + e \text{?} )$ | |

$\text{?} \text{indicates text missing or illegible when filed}$

Table 3 indicates the conditions in which the desired signals D_{I}LO_{I} and D_{Q}LO_{Q} are in phase and the image signals IM_{I}LO_{I} and IM_{Q}LO_{Q} are in antiphase at the output terminal 210, provided that the frequency of the desired signal D is F_{LO}+F_{IF} and the frequency of the image signal IM is F_{LO}−F_{IF}. In Table 3, when the phase rotation amount of the phase of the local signal LO_{Q} with respect to the local signal LO_{I} is about +90°, the phase rotation amount of the desired signal D_{QP} with respect to the desired signal D_{IP} is about +90°, and the phase rotation amount of the desired signal D_{QN} with respect to the desired signal D_{IN} is about −90° in the SAW phase shifter circuit 22A. When the phase rotation amount of the phase of the local signal LO_{Q} with respect to the local signal LO_{I} is about −90°, the phase rotation amount of the desired signal D_{QP} with respect to the desired signal D_{IP} is about −90°, and the phase rotation amount of the desired signal D_{QN} with respect to the desired signal D_{IN} is about +90° in the SAW phase shifter circuit 22A.

TABLE 4
F_{RF} = F_{LO} + F_{IF}, θ_{LOI} = 0°. Q_{LOQ} = +90°, mixer differential output, SAW device differential input/non-differential output

| | | | | | | Phase | | |
|---|---|---|---|---|---|---|---|---|
| | | | | | Output | rotation | | |
| | | | | | phase | amount | | |
| | | | | | of | of two- | | |
| | Input of | Local signal | Ter- | Output of | mixer | stage | Output of | Quiput of |
| Signal | mixer 10A | (phase) | minal | mixer 10A | 10A | filter | two-stage filler | SAW device 2QA |
| De- sired | $+ \frac{A \text{?}}{4} ( e \text{?} + e \text{?} )$ | $\frac{e \text{?} + e \text{?}}{2}$ | I+ | $+ \frac{A \text{?}}{8} ( e \text{?} + e \text{?} )$ | 0 | 0 | $+ {B}_{SAW} + \frac{A \text{?}}{8} ( e \text{?} + e \text{?} )$ | $+ {B}_{SAW} + \frac{A \text{?}}{2} ( e \text{?} + e \text{?} )$ |
| signal | | | | | | | | |
| D | | | | | | | | |
| | $- \frac{A \text{?}}{4} ( e \text{?} + e \text{?} )$ | (0) | I− | $- \frac{A \text{?}}{8} ( e \text{?} + e \text{?} )$ | 0 | Π | $+ {B}_{SAW} + \frac{A \text{?}}{8} ( e \text{?} + e \text{?} )$ | |
| | $+ \frac{A \text{?}}{4} ( e \text{?} + e \text{?} )$ | $\frac{e \text{?} + e \text{?}}{2 j}$ | Q+ | $+ \frac{A \text{?}}{8} ( e \text{?} - e \text{?} )$ | $- \frac{π}{2}$ | $+ \frac{π}{2}$ | $+ {B}_{SAW} + \frac{A \text{?}}{8} ( e \text{?} + e \text{?} )$ | |
| | $- \frac{A \text{?}}{4} ( e \text{?} + e \text{?} )$ | (π/2) | Q− | $- \frac{A \text{?}}{8} ( e \text{?} - e \text{?} )$ | $+ \frac{π}{2}$ | $- \frac{π}{2}$ | $+ {B}_{SAW} + \frac{A \text{?}}{8} ( e \text{?} + e \text{?} )$ | |
| Image signal | $+ \frac{A \text{?}}{4} ( e \text{?} + e \text{?} )$ | $\frac{e \text{?} + e \text{?}}{2}$ | I+ | $+ \frac{A \text{?}}{8} ( e \text{?} + e \text{?} )$ | 0 | 0 | $+ {B}_{SAW} + \frac{A \text{?}}{8} ( e \text{?} + e \text{?} )$ | |
| IM | | | | | | | | |
| | $- \frac{A \text{?}}{4} ( e \text{?} + e \text{?} )$ | (0) | I− | $- \frac{A \text{?}}{8} ( e \text{?} + e \text{?} )$ | 0 | Π | $+ {B}_{SAW} + \frac{A \text{?}}{8} ( e \text{?} + e \text{?} )$ | |
| | $+ \frac{A \text{?}}{4} ( e \text{?} + e \text{?} )$ | $\frac{- e \text{?} + e \text{?}}{2 j}$ | Q+ | $- \frac{A \text{?}}{8} ( e \text{?} - e \text{?} )$ | $+ \frac{π}{2}$ | $+ \frac{π}{2}$ | $- {B}_{SAW} + \frac{A \text{?}}{8} ( e \text{?} + e \text{?} )$ | |
| | $- \frac{A \text{?}}{4} ( e \text{?} + e \text{?} )$ | (π/2) | Q− | $+ \frac{A \text{?}}{8} ( e \text{?} - e \text{?} )$ | $- \frac{π}{2}$ | $- \frac{π}{2}$ | $- {B}_{SAW} + \frac{A \text{?}}{8} ( e \text{?} + e \text{?} )$ | |

$\text{?} \text{indicates text missing or illegible when filed}$

Table 4 indicates the conditions in which the desired signals D_{I}LO_{I} and D_{Q}LO_{Q} are in phase and the image signals IM_{I}LO_{I} and IM_{Q}LO_{Q} are in antiphase at the output terminal 210, provided that the frequency of the desired signal D is F_{LO}−F_{IF} and the frequency of the image signal IM is F_{LO}+F_{IF}. In Table 4, when the phase rotation amount of the phase of the local signal LO_{Q} with respect to the local signal LO_{I} is about +90°, the phase rotation amount of the desired signal D_{QP} with respect to the desired signal Dip is about −90°, and the phase rotation amount of the desired signal D_{QN} with respect to the desired signal D_{IN} is about +90° in the SAW phase shifter circuit 22A. When the phase rotation amount of the phase of the local signal LO_{Q} with respect to the local signal LO_{I} is about −90°, the phase rotation amount of the desired signal D_{QP} with respect to the desired signal Dip is about +90°, and the phase rotation amount of the desired signal D_{QN} with respect to the desired signal D_{IN} is about −90° in the SAW phase shifter circuit 22A.

As indicated in Tables 3 and 4, when the phase difference between the local signals LO_{Q} and LO_{I} is a predetermined phase difference, ∞ is obtained as the image rejection ratio. Here, it is assumed that the required image rejection ratio IRR is, for example, about 10 dB in the receiver 1A according to the present modification, similar to the receiver 1 according to the example embodiment.

At this time, in the receiver 1A according to the present modification, when the frequency of the desired signal D is F_{LO}+F_{IF}, and the frequency of the image signal IM is F_{LO}−F_{IF}, the phase rotation amount of the I signal transferred from the input I-terminal 211a and the input I-terminal 211b to the output terminal 210 is α°. The phase rotation amount of the I_{P} signal transferred from the input I-terminal 211a to the output terminal 210 is greater than or equal to about (α+n×360−35.1)° and less than or equal to about (α+n×360+35.1)°. The phase rotation amount of the I_{N} signal transferred from the input I-terminal 211b to the output terminal 210 is greater than or equal to about (α+180+n×360−35.1)° and less than or equal to about (α+180+n×360+35.1)°. At this time, when the value obtained by subtracting the phase of the local signal that drives the mixer circuit 11A from the phase of the local signal that drives the mixer circuit 12A is about (+90+n×360)°, in the case where the phase rotation amount of the Q_{P} signal transferred from the input Q-terminal 212a to the output terminal 210 is β1°, and the phase rotation amount of the ON signal transferred from the input Q-terminal 212b to the output terminal 210 is β2°, Expression 20 is satisfied.

$$( α + 90 + n \times 360 - 35.1 ) \leq β 1 \leq ( α + 90 + n \times 360 + 35.1 ) \\ ( α - 90 + n \times 360 - 35.1 ) \leq β 2 \leq ( α - 90 + n \times 360 + 35.1 ) \qquad Expression 20$$

When the value obtained by subtracting the phase of the local signal that drives the mixer circuit 11A from the phase of the local signal that drives the mixer circuit 12A is (−90+n×360)°, Expression 21 is satisfied.

$$( α - 90 + n \times 360 - 35.1 ) \leq β1 \leq ( α - 90 + n \times 360 + 35.1 ) \\ ( α + 90 + n \times 360 - 35.1 ) \leq β2 \leq ( α + 90 + n \times 360 + 35.1 ) \qquad Expression 21$$

As such, for example, the image signal IM generated by the quadrature mixer 10A can be reduced or prevented by the SAW device 20A with an image rejection ratio of about 10 dB or more. Instead of providing circuit elements such as baluns and transformers, the SAW device 20A for phase conversion is provided between the output end of the quadrature mixer 10A and the signal output terminal 102. With this configuration, the low-loss miniaturized mixer-first receiver 1A is provided.

The radio frequency-signal frequency F_{RF} (=F_{LO}+F_{IF}) Can be changed by varying the local-signal frequency F_{LO}. The quadrature mixer 10A may be implemented by a double balanced mixer having excellent performance as a semiconductor circuit.

In the receiver 1A according to the present modification, when the frequency of the desired signal D is F_{LO}−F_{IF}, and the frequency of the image signal IM is F_{LO}+F_{IF}, the phase rotation amount of the I signal transferred from the input I-terminal 211a and the input I-terminal 211b to the output terminal 210 is α°. The phase rotation amount of the I_{P} signal transferred from the input I-terminal 211a to the output terminal 210 is greater than or equal to about (α+n×360−35.1)° and less than or equal to about (α+n×360+35.1)°. The phase rotation amount of the I_{N} signal transferred from the input I-terminal 211b to the output terminal 210 is greater than or equal to about (α+180+n×360−35.1)° and less than or equal to about (α+180+n×360+35.1)°. At this time, when the value obtained by subtracting the phase of the local signal that drives the mixer circuit 11A from the phase of the local signal that drives the mixer circuit 12A is about (+90+n×360)°, in the case where the phase rotation amount of the Q_{P} signal transferred from the input Q-terminal 212a to the output terminal 210 is 1°, and the phase rotation amount of the Q_{N} signal transferred from the input Q-terminal 212b to the output terminal 210 is β2°, Expression 21 is satisfied.

When the value obtained by subtracting the phase of the local signal that drives the mixer circuit 11A from the phase of the local signal that drives the mixer circuit 12A is about (−90+n×360)°, Expression 20 is satisfied.

As such, the radio frequency-signal frequency F_{RF} (=F_{LO}−F_{IF}) can be changed by varying the local-signal frequency Fro.

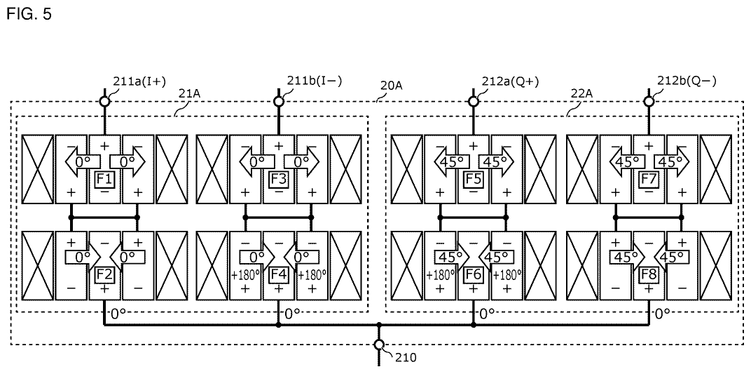

FIG. 5 illustrates an example of a circuit configuration of the SAW device 20A included in the receiver 1A according to the first modification. The SAW phase shifter circuit 21A includes a longitudinally coupled SAW filter F1 including three IDT electrodes and two reflectors disposed on a substrate having piezoelectricity, a longitudinally coupled SAW filter F2 including three IDT electrodes and two reflectors disposed on the substrate, a longitudinally coupled SAW filter F3 including three IDT electrodes and two reflectors disposed on the substrate, and a longitudinally coupled SAW filter F4 including three IDT electrodes and two reflectors disposed on the substrate.

The + terminal of the central IDT electrode of the SAW filter F1 is coupled to the input I-terminal 211a. The + terminals of the left and right IDT electrodes of the SAW filter F1 are coupled to the + terminals of the left and right IDT electrodes of the SAW filter F2. The + terminal of the central IDT electrode of the SAW filter F2 is coupled to the output terminal 210. The − terminals of the SAW filters F1 and F2 are grounded.

The + terminal of the central IDT electrode of the SAW filter F3 is coupled to the input I-terminal 211b. The + terminals of the left and right IDT electrodes of the SAW filter F3 are coupled to the − terminals of the left and right IDT electrodes of the SAW filter F4. The + terminal of the central IDT electrode of the SAW filter F4 is coupled to the output terminal 210. The − terminal of the SAW filter F3, the − terminal of the central IDT electrode of the SAW filter F4, and the + terminal of the left and right IDT electrodes are grounded.

With the configuration described above, in the SAW phase shifter circuit 21A, no phase rotation is introduced between the IDT electrodes included in the SAW filters F1 and F2. By contrast, a 180° phase rotation is introduced between the SAW filters F3 and F4. This is because the + terminals of the left and right IDT electrodes of the SAW filter F3 are coupled to the − terminals of the left and right IDT electrodes of the SAW filter F4.

The SAW phase shifter circuit 22A includes a longitudinally coupled SAW filter F5 including three IDT electrodes and two reflectors disposed on a substrate having piezoelectricity, a longitudinally coupled SAW filter F6 including three IDT electrodes and two reflectors disposed on the substrate, a longitudinally coupled SAW filter F7 including three IDT electrodes and two reflectors disposed on the substrate, and a longitudinally coupled SAW filter F8 including three IDT electrodes and two reflectors disposed on the substrate.

The + terminal of the central IDT electrode of the SAW filter F5 is coupled to the input Q-terminal 212a. The + terminals of the left and right IDT electrodes of the SAW filter F5 are coupled to the − terminals of the left and right IDT electrodes of the SAW filter F6. The + terminal of the central IDT electrode of the SAW filter F6 is coupled to the output terminal 210. The − terminal of the SAW filter F5, the − terminal of the central IDT electrode of the SAW filter F6, and the + terminal of the left and right IDT electrodes are grounded.

The + terminal of the central IDT electrode of the SAW filter F7 is coupled to the input Q-terminal 212b. The + terminals of the left and right IDT electrodes of the SAW filter F7 are coupled to the + terminals of the left and right IDT electrodes of the SAW filter F8. The + terminal of the central IDT electrode of the SAW filter F8 is coupled to the output terminal 210. The − terminal of the SAW filter F7 and the − terminal of the SAW filter F8 are grounded.

With the configuration described above, in the SAW phase shifter circuit 22A, a 45° phase rotation is introduced between the central IDT electrode and the left and right IDT electrodes of the SAW filter F5, and a 45° phase rotation is introduced between the left and right IDT electrodes and the central IDT electrode of the SAW filter F6. This is because the SAW filters F5 and F6 differ from the SAW filters F1 and F2 in terms of the distance between the central IDT electrode and the left and right IDT electrodes and the distance between the left and right IDT electrodes and the reflectors. Further, a 180° phase rotation is introduced between the SAW filters F5 and F6. This is because the + terminals of the left and right IDT electrodes of the SAW filter F5 are coupled to the − terminals of the left and right IDT electrodes of the SAW filter F6. By contrast, a 45° phase rotation is introduced between the central IDT electrode and the left and right IDT electrodes of the SAW filter F7, and a 45° phase rotation is introduced between the left and right IDT electrodes and the central IDT electrode of the SAW filter F8. This is because the SAW filters F7 and F8 differ from the SAW filters F1 and F2 in terms of the distance between the central IDT electrode and the left and right IDT electrodes and the distance between the left and right IDT electrodes and the reflectors.

In the configuration described above, the phase rotation amount of the I_{P} signal transferred from the input I-terminal 211a to the output terminal 210 is about 0°, and the phase rotation amount of the I_{N} signal transferred from the input I-terminal 211b to the output terminal 210 is about 180°. The phase rotation amount of the Q_{P} signal transferred from the input Q-terminal 212a to the output terminal 210 is about −90°, and the phase rotation amount of the Q_{N} signal transferred from the input Q-terminal 212b to the output terminal 210 is about +90°.

Because multiple SAW filters are cascade-connected, the configuration described above achieves a steeper attenuation characteristic and greater attenuation compared to a single SAW filter. Furthermore, by reducing the phase rotation amount per stage of the SAW filter to less than about 90°, a phase rotation of about 90° can be introduced by the SAW phase shifter circuit 22A with respect to the SAW phase shifter circuit 21A. This configuration easily matches the amplitude characteristics of the I signal and the Q signal.

Moreover, by reversing the polarities of the IDT electrodes of the SAW filter either positively or negatively, or by changing the IDT electrode distance by about ½ wavelength, the phase of the SAW device 20A can be inverted by about 180°.

A receiver 1B according to a second modification of an example embodiment of the present invention may be provided by changing the output of the SAW device 20A in the receiver 1A according to the first modification to differential outputs. The receiver 1B includes a quadrature mixer 10A, an SAW device 20B, an antenna connection terminal 101, and a signal output terminal 102. The SAW device 20B is an example of an acoustic wave device. The SAW device 20B includes SAW phase shifter circuits 21B and 22B, input I-terminals 211a and 211b, input Q-terminals 212a and 212b, and an output terminals 210a and an output terminals 210b.

The receiver 1B according to the present modification differs from the receiver 1A according to the first modification only in the configuration of the output terminals of the SAW phase shifter circuits 21B and 22B. The following describes the receiver 1B according to the present modification with a main focus on features different from the receiver 1A according to the first modification, and descriptions of the same features will not be repeated. In the receiver 1B according to the present modification, the output terminal 210a (fifth differential output terminal) of the SAW phase shifter circuit 21B and the output terminal 210b (sixth differential output terminal) of the SAW phase shifter circuit 22B are provided in place of the output terminal 210.

In this case, a radio-frequency signal including a desired signal D_{P} and an image signal IM_{P} is input to the input terminal 110a, and a radio-frequency signal including a desired signal D_{N} and an image signal IM_{N} is input to the input terminal 110b, and the radio-frequency signals are divided between the mixer circuits 11A and 12A. At this time, the desired signals Dip and DIN and the image signals IM_{IP} and IM_{IN} input to the mixer circuit 11A are modulated to frequencies (−F_{IF}) and (+F_{IF}). The desired signal D_{IP} and the image signals.

IM_{IP} are in phase, and the desired signal D_{IN} and the image signal IMIN are in phase. A desired signal D_{QP} and an image signal IM_{QP} input to the mixer circuit 12A are modulated to the frequencies (−F_{IF}) and (+F_{IF}). The desired signal D_{QP} is rotated by about 90° (or about −90°) with respect to the desired signal D_{IP}. The desired signal D_{QN} is rotated by about 90° (or about −90°) with respect to the desired signal D_{IN}. The image signal IM_{QP} is rotated by about −90° (or about 90°) with respect to the image signal IM_{IP}. The image signal IM_{QN} is rotated by about −90° (or about 90°) with respect to the image signal IM_{IN}.

Tables 5 and 6 indicate the relationships between the output signals output to the output terminals 210a and 210b, the phase of the local signal to be multiplied by the quadrature mixer 10A, and the phase rotation amount (two-stage filter phase rotation amount) of the SAW device 20A (the SAW device 20B), for the desired signal D and the image signal IM.

TABLE 5
F_{RF} = F_{LO} + F_{IF}, θ_{LOI} = 0°. Q_{LOQ} = +90°, mixer differential output, SAW device differential input/non-differential output

| | | | | | | Phase | | |
|---|---|---|---|---|---|---|---|---|
| | | | | | Output | rotation | | |
| | | | | | phase | amount | | |
| | | | | | of | of two- | | |
| | | Local signal | | Output of mixer | mixer | stage | Output of two-stage | Output of SAW device |
| Signal | Input of mixer 10A | (phase) | Terminal | 10A | 10A | filter | filter | 20B |
| Desired signal D | $+ \frac{A \text{?}}{4} ( e \text{?} + e \text{?}$ | $\frac{e \text{?} + e \text{?}}{2}$ | I+ | $+ \frac{{A}_{RF}}{8} ( e \text{?} + e \text{?}$ | 0 | 0 | $+ {B}_{SAW} \frac{{A}_{RF}}{8} ( e \text{?} + e \text{?}$ | $+ {B}_{SAW} \frac{{A}_{RF}}{4} ( e \text{?} + e \text{?}$ |
| | $- \frac{A \text{?}}{4} ( e \text{?} + e \text{?}$ | (0) | I− | $- \frac{{A}_{RF}}{8} ( e \text{?} + e \text{?}$ | 0 | Π | $+ {B}_{SAW} \frac{{A}_{RF}}{8} ( e \text{?} + e \text{?}$ | |
| | $+ \frac{A \text{?}}{4} ( e \text{?} + e \text{?}$ | $\frac{- e \text{?} + e \text{?}}{2 j}$ | Q+ | $+ \frac{{A}_{RF}}{8} ( e \text{?} - e \text{?} )$ | $- \frac{π}{2}$ | $- \frac{π}{2}$ | $- {B}_{SAW} \frac{{A}_{RF}}{8} ( e \text{?} + e \text{?}$ | $- {B}_{SAW} \frac{{A}_{RF}}{4} ( e \text{?} + e \text{?}$ |
| | $- \frac{A \text{?}}{4} ( e \text{?} + e \text{?}$ | (π/2) | Q− | $- \frac{{A}_{RF}}{8} ( e \text{?} - e \text{?} )$ | $+ \frac{π}{2}$ | $+ \frac{π}{2}$ | $- {B}_{SAW} \frac{{A}_{RF}}{8} ( e \text{?} + e \text{?}$ | |
| Image signal IM | $+ \frac{A \text{?}}{4} ( e \text{?} + e \text{?}$ | $\frac{e \text{?} + e \text{?}}{2}$ | I+ | $+ \frac{{A}_{IM}}{8} ( e \text{?} + e \text{?}$ | 0 | 0 | $+ {B}_{SAW} \frac{{A}_{IM}}{8} ( e \text{?} + e \text{?}$ | $+ {B}_{SAW} \frac{{A}_{IM}}{4} ( e \text{?} + e \text{?}$ |
| | $- \frac{{A}_{IM}}{4} ( e \text{?} + e \text{?}$ | (0) | I− | $- \frac{{A}_{IM}}{8} ( e \text{?} + e \text{?} )$ | 0 | Π | $+ {B}_{SAW} \frac{{A}_{IM}}{8} ( e \text{?} + e \text{?}$ | |
| | $+ \frac{{A}_{IM}}{4} ( e \text{?} + e \text{?}$ | $\frac{- e \text{?} + e \text{?}}{2 j}$ | Q+ | $- \frac{{A}_{IM}}{8} ( e \text{?} + e \text{?} )$ | $+ \frac{π}{2}$ | $- \frac{π}{2}$ | $+ {B}_{SAW} \frac{{A}_{IM}}{8} ( e \text{?} + e \text{?}$ | $+ {B}_{SAW} \frac{{A}_{IM}}{4} ( e \text{?} + e \text{?}$ |
| | $- \frac{{A}_{IM}}{4} ( e \text{?} + e \text{?}$ | (π/2) | Q− | $+ \frac{{A}_{IM}}{8} ( e \text{?} - e \text{?}$ | $- \frac{π}{2}$ | $+ \frac{π}{2}$ | $+ {B}_{SAW} \frac{{A}_{IM}}{8} ( e \text{?} + e \text{?}$ | |

$\text{?} \text{indicates text missing or illegible when filed}$

Table 5 indicates the conditions in which the desired signal D_{I}LO_{I} at the output terminal 210a and the desired signal D_{Q}LO_{Q} at the output terminal 210b are in antiphase and the image signal IM LO_{I} at the output terminal 210a and the image signal IM_{Q}LO_{Q} at the output terminal 210b are in phase, provided that the frequency of the desired signal D is F_{LO}+F_{IF} and the frequency of the image signal IM is F_{LO}−F_{IF}. In Table 5, when the phase rotation amount of the phase of the local signal LO_{Q} with respect to the local signal LO_{I} is about +90°, the phase rotation amount of the desired signal D_{QP} with respect to the desired signal D_{IP} is about −90°, and the phase rotation amount of the desired signal D_{QN} with respect to the desired signal D_{IN} is about +90° in the SAW phase shifter circuit 22B. When the phase rotation amount of the phase of the local signal LO_{Q} with respect to the local signal LO_{I} is about −90°, the phase rotation amount of the desired signal D_{QP} with respect to the desired signal D_{IP} is about +90°, and the phase rotation amount of the desired signal D_{Q} with respect to the desired signal D_{IN} is about −90° in the SAW phase shifter circuit 22B.

TABLE 6
F_{RF} = F_{LO} + F_{IF}, θ_{LOI} = 0°. Q_{LOQ} = +90°, mixer differential output, SAW device differential input/non-differential output

| | | | | | Output |
|---|---|---|---|---|---|
| | | | | | phase |
| | | | | | of |
| | | Local signal | | | mixer |
| Signal | Input of mixer 10A | (phase) | Terminal | Output of mixer 10A | 10A |
| Desired signal D | $+ \frac{{A}_{RF}}{4} ( {e}^{j ( {ω}_{LO} + {ω}_{IF} )} \text{?} + ( {e}^{- j} \text{?} )$ | $\frac{{e}^{j ω} \text{?} + {e}^{- j ω} \text{?}}{2}$ | I+ | $+ \frac{{A}_{RF}}{8} ( {e}^{j ω} \text{?} + {e}^{- j ω} \text{?} )$ | 0 |
| | $- \frac{{A}_{RF}}{4} ( {e}^{j ( {ω}_{LO} + {ω}_{IF} )} \text{?} + ( {e}^{- j} \text{?} )$ | (0) | I− | $- \frac{{A}_{RF}}{8} ( {e}^{j ω} \text{?} + {e}^{- j ω} \text{?} )$ | 0 |
| | $+ \frac{{A}_{RF}}{4} ( {e}^{j ( {ω}_{LO} + {ω}_{IF} )} \text{?} + ( {e}^{- j} \text{?} )$ | $\frac{- {e}^{j ω} \text{?} + {e}^{- j ω} \text{?}}{2 j}$ | Q+ | $- \frac{{A}_{RF}}{8 j} ( {e}^{j ω} \text{?} - {e}^{- j ω} \text{?} )$ | $+ \frac{π}{2}$ |
| | $- \frac{{A}_{RF}}{4} ( {e}^{j ( {ω}_{LO} + {ω}_{IF} )} \text{?} + ( {e}^{- j} \text{?} )$ | (π/2) | Q− | $+ \frac{{A}_{RF}}{8 j} ( {e}^{j ω} \text{?} - {e}^{- j ω} \text{?} )$ | $- \frac{π}{2}$ |
| Image signal IM | $+ \frac{{A}_{IM}}{4} ( {e}^{j ( {ω}_{LO} + {ω}_{IF} )} \text{?} + ( {e}^{- j} \text{?} )$ | $\frac{{e}^{j ω} \text{?} + {e}^{- j ω} \text{?}}{2}$ | I+ | $+ \frac{{A}_{IM}}{8} ( {e}^{j ω} \text{?} + {e}^{- j ω} \text{?} )$ | 0 |
| | $- \frac{{A}_{IM}}{4} ( {e}^{j ( {ω}_{LO} + {ω}_{IF} )} \text{?} + ( {e}^{- j} \text{?} )$ | (0) | I− | $- \frac{{A}_{IM}}{8} ( {e}^{j ω} \text{?} + {e}^{- j ω} \text{?} )$ | 0 |
| | $+ \frac{{A}_{IM}}{4} ( {e}^{j ( {ω}_{LO} + {ω}_{IF} )} \text{?} + ( {e}^{- j} \text{?} )$ | $\frac{- {e}^{j ω} \text{?} + {e}^{- j ω} \text{?}}{2 j}$ | Q+ | $+ \frac{{A}_{IM}}{8 j} ( {e}^{j ω} \text{?} - {e}^{- j ω} \text{?} )$ | $- \frac{π}{2}$ |
| | $- \frac{{A}_{IM}}{4} ( {e}^{j ( {ω}_{LO} + {ω}_{IF} )} \text{?} + ( {e}^{- j} \text{?} )$ | (π/2) | Q− | $- \frac{{A}_{IM}}{8 j} ( {e}^{j ω} \text{?} - {e}^{- j ω} \text{?} )$ | $+ \frac{π}{2}$ |

| | Phase | | |
|---|---|---|---|
| | rotation | | |
| | amount | | |
| | of two- | | |
| | stage | | |
| Signal | filter | Output of two-stage filter | Output of SAW device 20B |
| Desired signal D | 0 | $+ {B}_{SAW} \frac{{A}_{RF}}{8} ( {e}^{j ω} \text{?} + {e}^{- j ω} \text{?} )$ | $+ {B}_{SAW} \frac{{A}_{RF}}{4} ( {e}^{j ω} \text{?} + {e}^{- j ω} \text{?} )$ |
| | Π | $+ {B}_{SAW} \frac{{A}_{RF}}{8} ( {e}^{j ω} \text{?} + {e}^{- j ω} \text{?} )$ | $+ {B}_{SAW} \frac{{A}_{RF}}{4} ( {e}^{j ω} \text{?} + {e}^{- j ω} \text{?} )$ |
| | $+ \frac{π}{2}$ | $- {B}_{SAW} \frac{{A}_{RF}}{8} ( {e}^{j ω} \text{?} + {e}^{- j ω} \text{?} )$ | $+ {B}_{SAW} \frac{{A}_{IM}}{4} ( {e}^{j ω} \text{?} + {e}^{- j ω} \text{?} )$ |
| | $- \frac{π}{2}$ | $- {B}_{SAW} \frac{{A}_{RF}}{8} ( {e}^{j ω} \text{?} + {e}^{- j ω} \text{?} )$ | $+ {B}_{SAW} \frac{{A}_{IM}}{4} ( {e}^{j ω} \text{?} + {e}^{- j ω} \text{?} )$ |
| Image signal IM | 0 | $+ {B}_{SAW} \frac{{A}_{IM}}{8} ( {e}^{j ω} \text{?} + {e}^{- j ω} \text{?} )$ | |
| | Π | $+ {B}_{SAW} \frac{{A}_{IM}}{8} ( {e}^{j ω} \text{?} + {e}^{- j ω} \text{?} )$ | |
| | $+ \frac{π}{2}$ | $+ {B}_{SAW} \frac{{A}_{IM}}{8} ( {e}^{j ω} \text{?} + {e}^{- j ω} \text{?} )$ | |
| | $- \frac{π}{2}$ | $+ {B}_{SAW} \frac{{A}_{IM}}{8} ( {e}^{j ω} \text{?} + {e}^{- j ω} \text{?} )$ | |

$\text{?} \text{indicates text missing or illegible when filed}$

Table 6 indicates the conditions in which the desired signal D_{I}LO_{I} at the output terminal 210a and the desired signal D_{Q}LO_{Q} at the output terminal 210b are in antiphase and the image signal IM_{I}LO_{I} at the output terminal 210a and the image signal IM_{Q}LO_{Q} at the output terminal 210b are in phase, provided that the frequency of the desired signal D is F_{LO}−F_{IF} and the frequency of the image signal IM is F_{LO}+F_{IF}. In Table 6, when the phase rotation amount of the phase of the local signal LO_{Q} with respect to the local signal LO_{I} is about +90°, the phase rotation amount of the desired signal D_{QP} with respect to the desired signal Die is about +90°, and the phase rotation amount of the desired signal D_{QN} with respect to the desired signal D_{IN} is about −90° in the SAW phase shifter circuit 22B. When the phase rotation amount of the phase of the local signal LO_{Q} with respect to the local signal LO_{I} is about −90°, the phase rotation amount of the desired signal D_{QP} with respect to the desired signal Dip is about −90°, and the phase rotation amount of the desired signal D_{QN} with respect to the desired signal D_{IN} is about +90° in the SAW phase shifter circuit 22B.

As indicated in Tables 5 and 6, when the phase difference between the local signals LO_{Q} and LO_{I} is a predetermined phase difference, ∞ is obtained as the image rejection ratio. Here, for example, it is assumed that the required image rejection ratio IRR is about 10 dB in the receiver 1B according to the present modification, similar to the receiver 1 according to the example embodiment.

At this time, in the receiver according to the present modification, when the frequency of the desired signal D is F_{LO}+F_{IF}, and the frequency of the image signal IM is F_{LO}−F_{IF}, the phase rotation amount of the I signal transferred from the input I-terminal 211a and the input I-terminal 211b to the output terminal 210a is °. The phase rotation amount of the I_{P} signal transferred from the input I-terminal 211a to the output terminal 210a is greater than or equal to about (α+n×360−35.1)° and less than or equal to about (α+n×360+35.1)°. The phase rotation amount of the I_{N} signal transferred from the input I-terminal 211b to the output terminal 210a is greater than or equal to about (α+180+n×360−35.1)° and less than or equal to about (α+180+n×360+35.1)°. At this time, when the value obtained by subtracting the phase of the local signal that drives the mixer circuit 11A from the phase of the local signal that drives the mixer circuit 12A is about (+90+n×360)°, in the case where the phase rotation amount of the Q_{P} signal transferred from the input Q-terminal 212a to the output terminal 210b is β3°, and the phase rotation amount of the ON signal transferred from the input Q-terminal 212b to the output terminal 210b is β4°, Expression 22 is satisfied.

$$( α - 90 + n \times 360 - 35.1 ) \leq β3 \leq ( α - 90 + n \times 360 + 35.1 ) \\ ( α + 90 + n \times 360 - 35.1 ) \leq β4 \leq ( α + 90 + n \times 360 + 35.1 ) \qquad Expression 22$$

When the value obtained by subtracting the phase of the local signal that drives the mixer circuit 11A from the phase of the local signal that drives the mixer circuit 12A is (−90+n×360)°, Expression 23 is satisfied.

$$( α + 90 + n \times 360 - 35.1 ) \leq β3 \leq ( α + 90 + n \times 360 + 35.1 ) \\ ( α - 90 + n \times 360 - 35.1 ) \leq β 4 \leq ( α - 90 + n \times 360 + 35.1 ) \qquad Expression 23$$

As such, the image signal IM generated by the quadrature mixer 10A can be reduced or prevented by the SAW device 20B with an image rejection ratio of about 10 dB or more. Instead of providing circuit elements such as baluns and transformers, the SAW device 20B for phase conversion is provided between the output end of the quadrature mixer 10A and the signal output terminal 102. With this configuration, the low-loss miniaturized mixer-first receiver is provided.

The radio frequency-signal frequency F_{RF} (=F_{LO}+F_{IF}) can be changed by varying the local-signal frequency F_{LO}. The quadrature mixer 10A may be implemented by a double balanced mixer having excellent performance as a semiconductor circuit.

In the according to the present receiver 1B modification, when the frequency of the desired signal D is F_{LO}−F_{IF}, and the frequency of the image signal IM is F_{LO}+F_{IF}, the phase rotation amount of the I signal transferred from the input I-terminal 211a and the input I-terminal 211b to the output terminal 210a is α°. The phase rotation amount of the I_{P} signal transferred from the input I-terminal 211a to the output terminal 210a is greater than or equal to about (α+n×360−35.1)° and less than or equal to about (α+n×360+35.1)°. The phase rotation amount of the I_{N} signal transferred from the input I-terminal 211b to the output terminal 210a is greater than or equal to about (α+180+n×360−35.1)° and less than or equal to about (α+180+n×360+35.1)°. At this time, when the value obtained by subtracting the phase of the local signal that drives the mixer circuit 11A from the phase of the local signal that drives the mixer circuit 12A is about (+90+n×360)°, in the case where the phase rotation amount of the Q_{P} signal transferred from the input Q-terminal 212a to the output terminal 210b is β3°, and the phase rotation amount of the Q_{N} signal transferred from the input Q-terminal 212b to the output terminal 210b is β4°, Expression 23 is satisfied.

When the value obtained by subtracting the phase of the local signal that drives the mixer circuit 11A from the phase of the local signal that drives the mixer circuit 12A is about (−90+n×360)°, Expression 22 is satisfied.

As such, the radio frequency-signal frequency F_{RF} (=F_{LO}−F_{IF}) can be changed by varying the local-signal frequency F_{LO}.

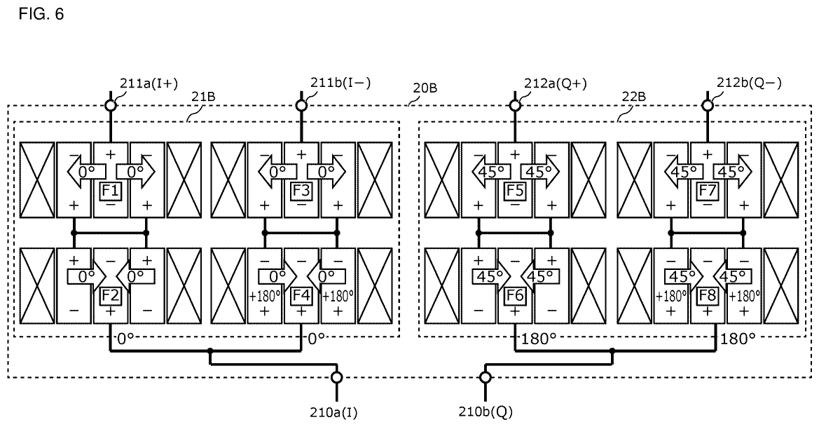

FIG. 6 illustrates an example of a circuit configuration of the SAW device included in the receiver 1B according to a second modification of an example embodiment of the present invention. The SAW phase shifter circuit 21B includes longitudinally coupled SAW filters F1, F2, F3, and F4.

The + terminal of the central IDT electrode of the SAW filter F1 is coupled to the input I-terminal 211a. The + terminals of the left and right IDT electrodes of the SAW filter F1 are coupled to the + terminals of the left and right IDT electrodes of the SAW filter F2. The + terminal of the central IDT electrode of the SAW filter F2 is coupled to the output terminal 210a. The − terminals of the SAW filters F1 and F2 are grounded.

The + terminal of the central IDT electrode of the SAW filter F3 is coupled to the input I-terminal 211b. The + terminals of the left and right IDT electrodes of the SAW filter F3 are coupled to the − terminals of the left and right IDT electrodes of the SAW filter F4. The + terminal of the central IDT electrode of the SAW filter F4 is coupled to the output terminal 210a. The − terminal of the SAW filter F3, the − terminal of the central IDT electrode of the SAW filter F4, and the + terminal of the left and right IDT electrodes are grounded.

With the configuration described above, in the SAW phase shifter circuit 21B, no phase rotation is introduced between the IDT electrodes included in the SAW filters F1 and F2. By contrast, a 180° phase rotation is introduced between the SAW filters F3 and F4.

The SAW phase shifter circuit 22B includes longitudinally coupled SAW filters F5, F6, F7, and F8.

The + terminal of the central IDT electrode of the SAW filter F5 is coupled to the input Q-terminal 212a. The + terminals of the left and right IDT electrodes of the SAW filter F5 are coupled to the + terminals of the left and right IDT electrodes of the SAW filter F6. The + terminal of the central IDT electrode of the SAW filter F6 is coupled to the output terminal 210b. The − terminals of the SAW filters F5 and F6 are grounded.

The + terminal of the central IDT electrode of the SAW filter F7 is coupled to the input Q-terminal 212b. The + terminals of the left and right IDT electrodes of the SAW filter F7 are coupled to the − terminals of the left and right IDT electrodes of the SAW filter F8. The + terminal of the central IDT electrode of the SAW filter F8 is coupled to the output terminal 210b. The − terminal of the SAW filter F7, the − terminal of the central IDT electrode of the SAW filter F8, and the + terminal of the left and right IDT electrodes are grounded.

With the configuration described above, in the SAW phase shifter circuit 22B, a 45° phase rotation is introduced between the central IDT electrode and the left and right IDT electrodes of the SAW filter F5, and a 45° phase rotation is introduced between the left and right IDT electrodes and the central IDT electrode of the SAW filter F6. By contrast, a 45° phase rotation is introduced between the central IDT electrode and the left and right IDT electrodes of the SAW filter F7, and a 45° phase rotation is introduced between the left and right IDT electrodes and the central IDT electrode of the SAW filter F8. Additionally, a 180° phase rotation is introduced between the SAW filters F7 and F8.

In the configuration described above, the phase rotation amount of the I_{P} signal transferred from the input I-terminal 211a to the output terminal 210a is about 0°, and the phase rotation amount of the I_{N} signal transferred from the input I-terminal 211b to the output terminal 210a is about 180°. The phase rotation amount of the Q_{P} signal transferred from the input Q-terminal 212a to the output terminal 210b is about +90°, and the phase rotation amount of the Q_{N} signal transferred from the input Q-terminal 212b to the output terminal 210b is about −90°. As a result, the phase of the I_{P} signal at the output terminal 210a and the I_{N} signal at the output terminal 210a are both about 0°, and the phase of the Q_{P} signal at the output terminal 210b and the Q_{N} signal at the output terminal 210b are both about 180°.

Because multiple SAW filters are cascade-connected, the configuration described above achieves a steeper attenuation characteristic and greater attenuation compared to a single SAW filter. Furthermore, by reducing the phase rotation amount in one stage of the SAW filter to less than about 90°, a phase rotation of about 90° can be introduced by the SAW phase shifter circuit 22B with respect to the SAW phase shifter circuit 21B. This configuration easily matches the amplitude characteristics of the I signal and the Q signal.

Moreover, by reversing the polarities of the IDT electrodes of the SAW filter either positively or negatively, or by changing the IDT electrode distance by about ½ wavelength, the phase of the SAW phase shifter circuit 21B can be inverted by about 180°.

### OTHER EXAMPLE EMBODIMENTS

The receiver and the communication device according to the present invention have been described by using example embodiment and modifications, but the present invention is not limited to the example embodiment and modifications. The present invention also includes other modifications obtained by making various alterations to the example embodiments and modifications that occur to those skilled in the art without departing from the scope of the example embodiment, and various hardware devices incorporating the receiver or the communication device according to the present invention.

For example, the SAW devices 20, 20A, and 20B according to example embodiments and modifications are not limited to devices including surface acoustic waves. It is sufficient that the SAW devices 20, 20A, and 20B according to the example embodiments and modifications are devices including acoustic waves. Acoustic waves are not limited to surface acoustic waves, but may be acoustic waves that can be excited using IDT electrodes, that is, pseudo surface acoustic waves, boundary acoustic waves, or acoustic plate waves, for example. The devices utilizing the acoustic waves can define longitudinally coupled acoustic wave filters or acoustic wave phase shifter circuits described in the example embodiments, similar to surface acoustic waves.

For example, in the receiver and the communication device according to the example embodiments and modifications, matching elements such as inductors or capacitors, for example, and switching circuits may be coupled among the elements.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A receiver comprising:
a quadrature mixer to perform frequency conversion to convert a radio-frequency signal into an I signal and a Q signal that have a 90° phase difference from each other; and
an acoustic wave device to perform phase conversion on the I signal and the Q signal that are output from the quadrature mixer; wherein
in the acoustic wave device, when α° represents a phase rotation amount of the I signal, β° represents a phase rotation amount of the Q signal, and n is an integer:
$$( α + 90 + n \times 360 - 35.1 ) \leq β \leq ( α + 90 + n \times 360 + 35.1 ) , \\ or ( α - 90 + n \times 360 - 35.1 ) \leq β \leq ( α - 90 + n \times 360 + 35.1 ) .$$

2. A receiver comprising:
a quadrature mixer to perform frequency conversion to convert a radio-frequency signal into an I signal and a Q signal that have a 90° phase difference from each other; and
an acoustic wave device to perform phase conversion on the I signal and the Q signal that are output from the quadrature mixer; wherein
in the acoustic wave device, the 90° phase difference is generated by at least one acoustic wave device using a resonance mode.

3. The receiver according to claim 2, wherein
when α° represents a phase rotation amount of the I signal, β° represents a phase rotation amount of the Q signal, and n is an integer:
$$( α + 90 + n \times 360 - 35.1 ) \leq β \leq ( α + 90 + n \times 360 + 35.1 ) , \\ or ( α - 90 + n \times 360 - 35.1 ) \leq \leq ( α - 90 + n \times 360 + 35.1 ) ; and$$
the 90° phase difference between the α and the β is generated by the at least one acoustic wave device using a resonance mode.

4. The receiver according to claim 1, wherein
the I signal includes an I_{P} signal and an I_{N} signal that are in antiphase with each other;
the Q signal includes a Q_{P} signal and a Q_{N} signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, and the second differential output I-terminal being configured to output the I_{N} signal;
a first differential output Q-terminal and a second differential output Q-terminal, the first differential output I terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth non-differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth non-differential output terminal, a phase rotation amount of the I_{P} signal transferred from the third differential input I-terminal to the fifth non-differential output terminal is greater than or equal to about (α+n×360−35.1)° and less than or equal to about (α+n×360+35.1)°, and a phase rotation amount of the I_{N} signal transferred from the fourth differential input I-terminal to the fifth non-differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where β1° represents a phase rotation amount of the Q_{P} signal transferred from the third differential input Q-terminal to the fifth non-differential output terminal, and β2° represents a phase rotation amount of the Q_{N} signal transferred from the fourth differential input Q-terminal to the fifth non-differential output terminal:
$$( α + 90 + n \times 360 - 35.1 ) \leq β1 \leq ( α + 90 + n \times 360 + 35.1 ) ; and \\ ( α - 90 + n \times 360 - 35.1 ) \leq β2 \leq ( α - 90 + n \times 360 + 35.1 ) ; and$$
when a value obtained by subtracting a phase of a local signal that drives the first mixer from a phase of a local signal that drives the second mixer is about (−90+n×360)°:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) .$$

5. The receiver according to claim 1, wherein
the I signal includes an I_{P} signal and an I_{N} signal that are in antiphase with each other;
the Q signal includes a Q_{P} signal and a ON signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth non-differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth non-differential output terminal, a phase rotation amount of the I_{P} signal transferred from the third differential input I-terminal to the fifth non-differential output terminal is greater than or equal to about (α+n×360−35.1)° and less than or equal to about (α+n×360+35.1) °, and a phase rotation amount of the I_{N} signal transferred from the fourth differential input I-terminal to the fifth non-differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where 31° represents a phase rotation amount of the Q_{P} signal transferred from the third differential input Q-terminal to the fifth non-differential output terminal, and β2° represents a phase rotation amount of the Q_{N} signal transferred from the fourth differential input Q-terminal to the fifth non-differential output terminal:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) .$$

6. The receiver according to claim 1, wherein
the I signal includes an I_{P} signal and an I_{N} signal that are in antiphase with each other;
the Q signal includes a Q_{P} signal and a ON signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth differential output terminal and a sixth differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth differential output terminal, a phase rotation amount of the I_{P} signal transferred from the third differential input I-terminal to the fifth differential output terminal is greater than or equal to about (α+n×360−35.1)° and less than or equal to about (α+n×360+35.1)°, and a phase rotation amount of the I_{N} signal transferred from the fourth differential input I-terminal to the fifth differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where β3° represents a phase rotation amount of the Q_{P} signal transferred from the third differential input Q-terminal to the sixth differential output terminal, and β4° represents a phase rotation amount of the Q_{N} signal transferred from the fourth differential input Q-terminal to the sixth differential output terminal:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) .$$

7. The receiver according to claim 1, wherein
the I signal includes an I_{P} signal and an I_{N} signal that are in antiphase with each other;
the Q signal includes a Q_{P} signal and a Q_{N} signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal; and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth differential output terminal and a sixth differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth differential output terminal, a phase rotation amount of the I_{P} signal transferred from the third differential input I-terminal to the fifth differential output terminal is greater than or equal to about (α+n×360−35.1)° and less than or equal to about (α+n×360+35.1), and a phase rotation amount of the I_{N} signal transferred from the fourth differential input I-terminal to the fifth differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where 3° represents a phase rotation amount of the Q_{P} signal transferred from the third differential input Q-terminal to the sixth differential output terminal, and β4° represents a phase rotation amount of the Q_{N} signal transferred from the fourth differential input Q-terminal to the sixth differential output terminal:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) .$$

8. The receiver according to claim 1, wherein the acoustic wave device includes a surface acoustic wave filter with a pass band including a frequency of the I signal and a frequency of the Q signal.

9. The receiver according to claim 1, wherein the acoustic wave device includes a longitudinally coupled surface acoustic wave filter.

10. The receiver according to claim 1, wherein
the acoustic wave device includes a plurality of phase shifter circuits cascade-connected to each other; and
a phase rotation amount of an output signal with respect to an input signal of each phase shifter circuit is less than about 90°.

11. The receiver according to claim 1, wherein
the acoustic wave device includes a plurality of phase shifter circuits;
each of the plurality of phase shifter circuits includes a plurality of interdigital transducer (IDT) electrodes in a surface acoustic wave propagation direction; and
signal phases are inverted between adjacent IDT electrodes among the plurality of IDT electrodes in at least one of the plurality of phase shifter circuits.

12. The receiver according to claim 1, wherein the acoustic wave is a surface acoustic wave, a pseudo surface acoustic wave, a boundary acoustic wave, or an acoustic plate wave.

13. A communication device comprising:
a signal processing circuit to process a radio-frequency signal; and
the receiver according to claim 1; wherein
the receiver is operable to transfer the radio-frequency signal between the signal processing circuit and an antenna.

14. The communication device according to claim 13, wherein
the I signal includes an I_{P} signal and an I_{N} signal that are in antiphase with each other;
the Q signal includes a Q_{P} signal and a Q_{N} signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, and the second differential output I-terminal being configured to output the I_{N} signal;
a first differential output Q-terminal and a second differential output Q-terminal, the first differential output I terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth non-differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth non-differential output terminal, a phase rotation amount of the I_{P} signal transferred from the third differential input I-terminal to the fifth non-differential output terminal is greater than or equal to about (α+n×360−35.1)° and less than or equal to about (α+n×360+35.1)°, and a phase rotation amount of the I_{N} signal transferred from the fourth differential input I-terminal to the fifth non-differential output terminal is greater than or equal to about (α+180+n×360-35.1)° and less than or equal to about (α+180+n×360+35.1)°;
when a value obtained by subtracting a phase of a local signal that drives the first mixer from a phase of a local signal that drives the second mixer is about (+90+n×360)°, in a case where β1° represents a phase rotation amount of the Q_{P} signal transferred from the third differential input Q-terminal to the fifth non-differential output terminal, and β2° represents a phase rotation amount of the Q_{N} signal transferred from the fourth differential input Q-terminal to the fifth non-differential output terminal:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) .$$

15. The communication device according to claim 13, wherein
the I signal includes an I_{P} signal and an I_{N} signal that are in antiphase with each other;
the Q signal includes a Q_{P} signal and a Q_{N} signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth non-differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth non-differential output terminal, a phase rotation amount of the I_{P} signal transferred from the third differential input I-terminal to the fifth non-differential output terminal is greater than or equal to about (α+n×360−35.1)° and less than or equal to about (α+n×360+35.1) °, and a phase rotation amount of the I_{N} signal transferred from the fourth differential input I-terminal to the fifth non-differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where 1° represents a phase rotation amount of the Q_{P} signal transferred from the third differential input Q-terminal to the fifth non-differential output terminal, and β2° represents a phase rotation amount of the ON signal transferred from the fourth differential input Q-terminal to the fifth non-differential output terminal:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β1 \leq ( α - 90 + n \times 360 + 35.1 ) ;$$
$$and$$
$$( α + 90 + n \times 360 - 35.1 ) \leq β2 \leq ( α + 90 + n \times 360 + 35.1 ) .$$

16. The communication device according to claim 13, wherein
the I signal includes an I_{P} signal and an I_{N} signal that are in antiphase with each other;
the Q signal includes a Q_{P} signal and a Q_{N} signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal, and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth differential output terminal and a sixth differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth differential output terminal, a phase rotation amount of the I_{P} signal transferred from the third differential input I-terminal to the fifth differential output terminal is greater than or equal to about (α+n×360−35.1)° and less than or equal to about (α+n×360+35.1)°, and a phase rotation amount of the I_{N} signal transferred from the fourth differential input I-terminal to the fifth differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where β3° represents a phase rotation amount of the Q_{P} signal transferred from the third differential input Q-terminal to the sixth differential output terminal, and β4° represents a phase rotation amount of the Q_{N} signal transferred from the fourth differential input Q-terminal to the sixth differential output terminal:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) ;$$
and
when a value obtained by subtracting a phase of a local signal that drives the first mixer from a phase of a local signal that drives the second mixer is about (−90+n×360)°:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) .$$

17. The communication device according to claim 13, wherein
the I signal includes an I_{P} signal and an I_{N} signal that are in antiphase with each other;
the Q signal includes a Q_{P} signal and a ON signal that are in antiphase with each other;
the quadrature mixer includes:
a first differential input terminal and a second differential input terminal to respectively receive signals that are in antiphase with each other;
a first differential output I-terminal and a second differential output I-terminal, the first differential output I-terminal being configured to output the I_{P} signal, the second differential output I-terminal being configured to output the I_{N} signal;
a first differential output Q-terminal and a second differential output Q-terminal, the first differential output I-terminal being configured to output the Q_{P} signal, the second differential output Q-terminal being configured to output the Q_{N} signal;
a first mixer coupled between the first differential input terminal and the second differential input terminal; and the first differential output I-terminal and the second differential output I-terminal; and
a second mixer coupled between the first differential input terminal and the second differential input terminal, and the first differential output Q-terminal and the second differential output Q-terminal;
the acoustic wave device includes:
a third differential input I-terminal and a fourth differential input I-terminal;
a third differential input Q-terminal and a fourth differential input Q-terminal; and
a fifth differential output terminal and a sixth differential output terminal;
the third differential input I-terminal is coupled to the first differential output I-terminal;
the fourth differential input I-terminal is coupled to the second differential output I-terminal;
the third differential input Q-terminal is coupled to the first differential output Q-terminal;
the fourth differential input Q-terminal is coupled to the second differential output Q-terminal; and
in the acoustic wave device, in a case where α° represents a phase rotation amount of the I signal transferred from the third differential input I-terminal and the fourth differential input I-terminal to the fifth differential output terminal, a phase rotation amount of the I_{P} signal transferred from the third differential input I-terminal to the fifth differential output terminal is greater than or equal to about (α+n×360−35.1)° and less than or equal to about (α+n×360+35.1), and a phase rotation amount of the I_{N} signal transferred from the fourth differential input I-terminal to the fifth differential output terminal is greater than or equal to about (α+180+n×360−35.1)° and less than or equal to about (α+180+n×360+35.1)°;
when a value obtained by subtracting a phase of a local signal that drives the first mixer from a phase of a local signal that drives the second mixer is about (+90+n×360)°, in a case where β3° represents a phase rotation amount of the Q_{P} signal transferred from the third differential input Q-terminal to the sixth differential output terminal, and β4° represents a phase rotation amount of the Q_{N} signal transferred from the fourth differential input Q-terminal to the sixth differential output terminal:
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) ;$$
and
when a value obtained by subtracting a phase of a local signal that drives the first mixer from a phase of a local signal that drives the second mixer is about (−90+n×360)°;
$$( α - 90 + n \times 360 - 35.1 ) \leq β3 \leq ( α - 90 + n \times 360 + 35.1 ) ;$$
$$and$$
$$( α + 90 + n \times 360 - 35.1 ) \leq β 4 \leq ( α + 90 + n \times 360 + 35.1 ) .$$

18. The communication device according to claim 13, wherein the acoustic wave device includes a surface acoustic wave filter with a pass band including a frequency of the I signal and a frequency of the Q signal.

19. The communication device according to claim 13, wherein the acoustic wave device includes a longitudinally coupled surface acoustic wave filter.

20. The communication device according to claim 13, wherein
the acoustic wave device includes a plurality of phase shifter circuits cascade-connected to each other; and
a phase rotation amount of an output signal with respect to an input signal of each phase shifter circuit is less than about 90°.
